(19) United States
(12) Patent Application Publication
(10) Pub. No.: US 2026/0099093 A1
(43) Pub. Date: Apr. 9, 2026

(54) PHOTOSENSITIVE RESIN COMPOSITION, METHOD FOR PRODUCING CURED RELIEF PATTERN USING SAME, AND METHOD FOR PRODUCING POLYIMIDE FILM USING SAME

(71) Applicant: ASAHI KASEI KABUSHIKI KAISHA, Tokyo (JP)

(72) Inventors: Keisuke WADA, Tokyo (JP); Mayuki YOSHIDA, Tokyo (JP)

(73) Assignee: ASAHI KASEI KABUSHIKI KAISHA, Tokyo (JP)

(21) Appl. No.: 19/124,375

(22) PCT Filed: Oct. 27, 2023
(86) PCT No.: PCT/JP2023/038954

§ 371 Date: Apr. 25, 2025

(30) Foreign Application Priority Data
Oct. 31, 2022 (JP) 2022-174360

(51) Int. Cl. G03F 7/004; G03F 7/028; G03F 7/038; G03F 7/40

(52) U.S. Cl. CPC G03F 7/0045; G03F 7/028; G03F 7/038; G03F 7/40

(57) ABSTRACT

The present disclosure provides a photosensitive resin composition which achieves high copper adhesion, while suppressing the occurrence of a copper void at the interface between a copper layer and a resin layer after a high temperature storage test and having little copper migration in a b-HAST test. A photosensitive resin composition according to the present disclosure contains the following components: (A) a polyimide precursor and/or a polyimide resin; (B) a tetrazole derivative; (C) a photopolymerization initiator; and (D) a solvent. The tetrazole derivative (B) has a pKa of 1.3 to 4.1, or is represented by general formula (1) or (2), or has a polar surface area (tPSA) of 81 to 200.

### FIELD

The present disclosure relates to a photosensitive resin composition, and a method for producing a cured relief pattern using the same, and a method for producing a polyimide film using the same. This application claims priority based on Japanese Patent Application No. 2022-174360 filed on Oct. 31, 2022, the disclosure of which is incorporated by reference herein.

### BACKGROUND

There have hitherto been used, as insulating materials of electronic components as well as passivation films, surface protective films and interlayer insulating films of semiconductor devices, polyimide resins, polybenzoxazole resins and phenol resins having excellent heat resistance, electrical properties and mechanical properties. Of these resins, those provided in the form of a photosensitive resin composition can be used to easily form a heat-resistant relief pattern film by a thermal imidization treatment due to coating, exposure, development and curing of the composition. Such photosensitive resin composition is characterized in that significant process reduction can be achieved as compared with conventional non-photosensitive materials.

On the other hand, the methods used to mount semiconductor devices on printed wiring boards (packaging structure) have changed in recent years from the viewpoints of improving the degree of integration and arithmetic function and reducing chip size. Structures are being employed in which a polyimide coating makes direct contact with the solder bump in the manner of the transition from conventional mounting methods using metal pins or lead-tin eutectic solder to higher density mounting methods such as ball grid arrays (BGA) or chip size packaging (CSP). Furthermore, a structure has also been proposed in which a plurality of rewiring layers, each having an area larger than the area of a semiconductor chip, is provided on the surface of the semiconductor chip, such as fan-out (FO) (see PTL 1).

Copper is often used for wiring in semiconductor devices, but in large-area packaging structures, the difference in thermal expansion coefficient between different materials causes stress, which can lead to peeling between copper and the interlayer insulating material, resulting in a deterioration in electrical properties. Therefore, materials used as interlayer insulating films are required to have high adhesion to copper.

Furthermore, in recent years, the use of semiconductor devices in automobiles and mobile phones has become remarkable, and semiconductor devices in these fields are required to have high reliability, and reliability tests are carried out in high-temperature environments.

### CITATION LIST

### Patent Literature

[PTL 1] U.S. Pat. No. 10,658,199
[PTL 2] JP 2012-194520 A

### SUMMARY

### Technical Problem

However, conventionally, in the high-temperature storage test of the above reliability tests, voids due to migration (hereinafter also referred to as “copper voids” in the present disclosure) may occur at the interface between the rewired copper layer and the resin layer after the test. If copper voids occur at the interface between the copper layer and the resin layer, the adhesion between them deteriorates. Migration of copper into a resin layer (hereinafter also referred to as “copper migration” in the present disclosure) can cause short circuits between wirings, particularly in semiconductor devices with fine wiring, and the performance of the insulating film cannot be fully exhibited. Therefore, there is a demand for a polyimide film which has little copper migration in a reliability test under high temperature and high humidity conditions (b-HAST: Biased Hughly Accelerated Stress Test) and does not cause short circuits for a long period of time.

An object of the present disclosure is to provide a photosensitive resin composition which has high copper adhesion, suppresses the generation of copper voids at the interface between the copper layer and the resin layer after a high-temperature storage test, and exhibits little copper migration in a b-HAST test. Suppression of copper migration in the b-HAST test leads to the formation of a polyimide film which is less likely to cause short circuits over a long period of time. Another object is to provide a method for forming a cured relief pattern using the photosensitive resin composition of the present disclosure, and a method for producing a polyimide film.

### Solution to Problem

The present inventors have found that the above problems can be solved by adding a specific tetrazole derivative to a photosensitive resin composition. Examples of embodiments of the present disclosure are listed in the following items [1] to [18].

[1]

A photosensitive resin composition comprising:
(A) a polyimide precursor and/or a polyimide resin,
(B) a tetrazole derivative,
(C) a photopolymerization initiator, and
(D) a solvent,
wherein the tetrazole derivative (B) has a pKa of 1.3 to 4.1.
   [2]

A photosensitive resin composition comprising:
(A) a polyimide precursor and/or a polyimide resin,
(B) a tetrazole derivative,
(C) a photopolymerization initiator, and
(D) a solvent,
wherein the tetrazole derivative (B) contains a compound represented by following general formula (1):

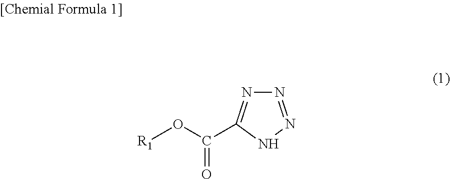

wherein, in formula (1), R₁ is a hydrogen atom, or a monovalent organic group selected from the group consisting of an alkyl group having 1 to 10 carbon atoms and an aryl group having 6 to 10 carbon atoms, and hydrogen atoms of the alkyl group and the aryl group may or may not be each independently substituted with at least one substituent selected from the group consisting of a halogen atom, a hydroxyl group, an alkoxysilyl group and an amino group, or following general formula (2):

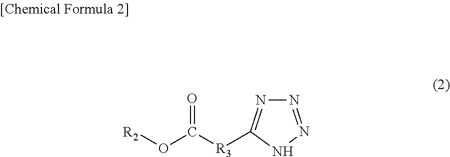

wherein, in formula (2), R₂ is a hydrogen atom, or a monovalent organic group selected from the group consisting of an alkyl group having 1 to 10 carbon atoms and an aryl group having 6 to 10 carbon atoms, R₃ is an alkylene group having 1 to 10 carbon atoms, and hydrogen atoms of the alkyl group, the aryl group and the alkylene group may or may not be each independently substituted with at least one substituent selected from the group consisting of a halogen atom, a hydroxyl group, an alkoxysilyl group and an amino group.
   [3]

A photosensitive resin composition comprising:
(A) a polyimide precursor and/or a polyimide resin,
(B) a tetrazole derivative,
(C) a photopolymerization initiator, and
(D) a solvent,
wherein the tetrazole derivative (B) has a polar surface area (tPSA) of 81 to 200.
   [4]

The photosensitive resin composition according to any one of items 1 to 3, wherein the content of the component (B) to 100 parts by weight of the component (A) is 0.01 to 10 parts by weight.

[5]

The photosensitive resin composition according to any one of items 1 to 4, wherein the tetrazole derivative (B) contains a compound represented by following general formula (3):

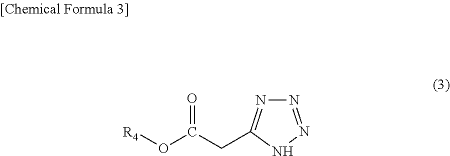

wherein, in formula (3), R₄ is a hydrogen atom, or a monovalent organic group selected from the group consisting of an alkyl group having 1 to 10 carbon atoms and an aryl group having 6 to 10 carbon atoms, and hydrogen atoms of the alkyl group and the aryl group may or may not be each independently substituted with at least one substituent selected from the group consisting of a halogen atom, a hydroxyl group, an alkoxysilyl group and an amino group.
   [6]

The photosensitive resin composition according to any one of items 1 to 5, wherein the tetrazole derivative (B) contains a compound represented by the following formula:

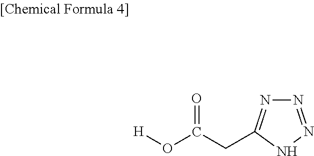

[7]

The photosensitive resin composition according to any one of items 1 to 6, further comprising (E) a radical polymerizable compound.

[8]

The photosensitive resin composition according to item 7, wherein the content of the component (E) to 100 parts by weight of the component (A) is 20 to 80 parts by weight.

[9]

The photosensitive resin composition according to any one of items 1 to 8, wherein the photosensitive resin composition includes the polyimide precursor, and the polyimide precursor is represented by following general formula (4):

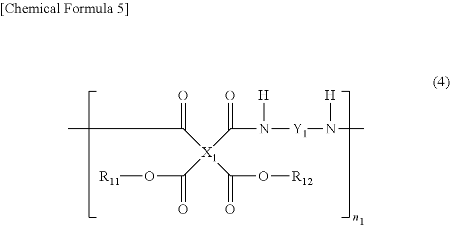

wherein, in formula (4), X₁ is a tetravalent organic group, Y₁ is a divalent organic group, n₁ is an integer of 2 to 150, and R₁₁ and R₁₂ each independently represent a hydrogen atom, or a monovalent organic group, and/or
the photosensitive resin composition includes the polyimide resin, and the polyimide resin includes a structural unit represented by following general formula (4′):

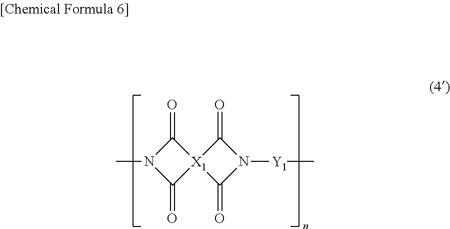

wherein, in formula (4′), X₁ is a tetravalent organic group, Y₁ is a divalent organic group, and n is an integer of 1 to 150.
   [10]

The photosensitive resin composition according to item 9 or 10, wherein, in the above general formula (4), at least one of R₁₁ and R₁₂ includes a structural unit represented by following general formula (5):

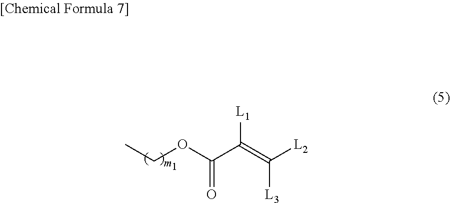

wherein, in formula (5), L₁, L₂ and L₃ are each independently a hydrogen atom, or a monovalent organic group having 1 to 3 carbon atoms, and m₁ is an integer of 2 to 10.
   [11]

The photosensitive resin composition according to item 9 or 10, wherein X₁ of the general formula (4′) is at least one selected from structures represented by following general formulas (6) to (14), or Y₁ of the above general formula (4′) is at least one selected from structures represented by following general formula (15) to (23):

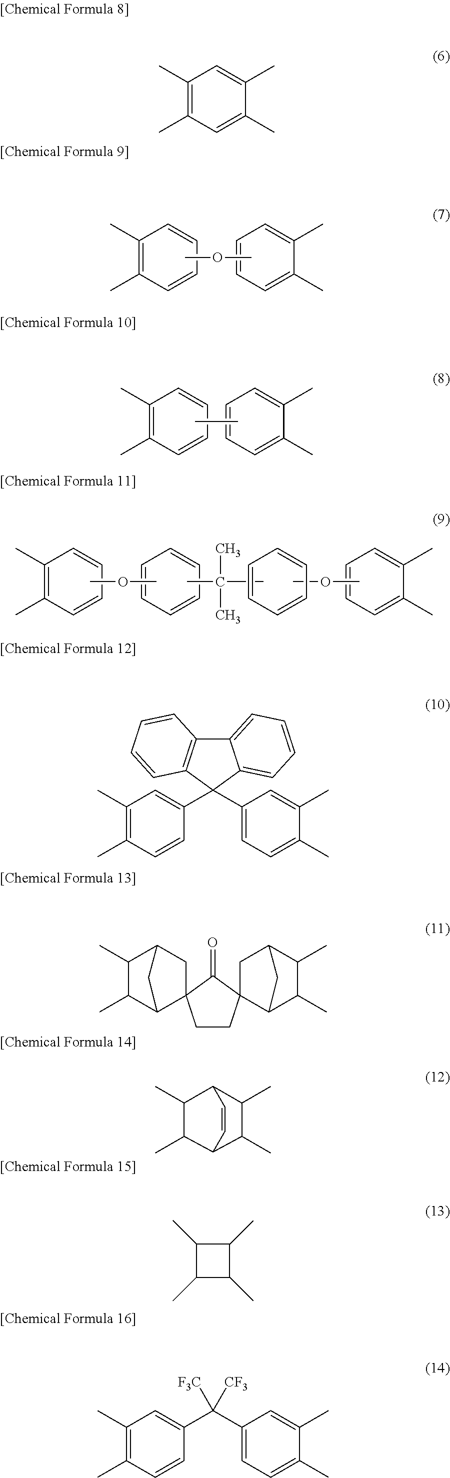

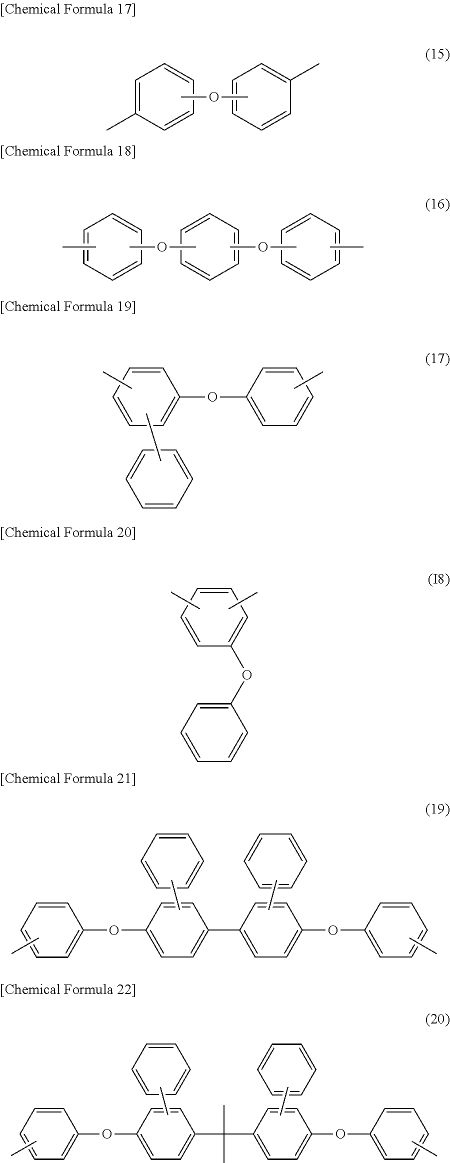

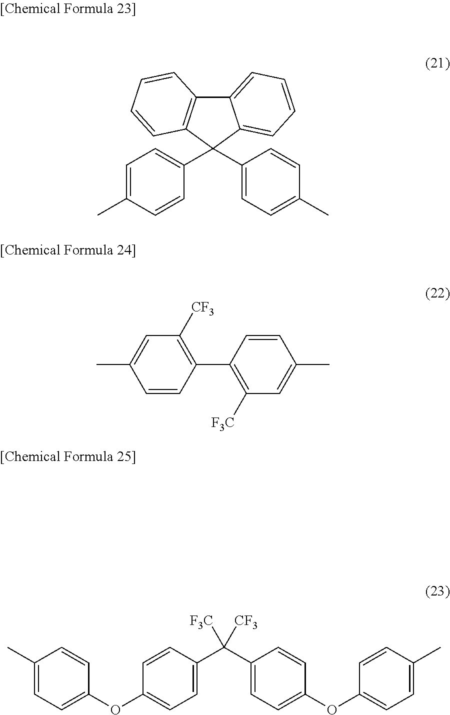

[12]

The photosensitive resin composition according to any one of items 1 to 11, further comprising (F) a thermal crosslinking agent.

[13]

The photosensitive resin composition according to any one of items 1 to 12, further comprising (K) an adhesion aid.

[14]

The photosensitive resin composition according to any one of items 1 to 13, wherein the photosensitive resin composition is a photosensitive resin composition for forming a surface protective film, an interlayer insulating film, a rewiring insulating film, a protective film for flip-chip devices, or a protective film of a semiconductor device having a bump structure.

[15]

A method for producing a cured relief pattern, which comprises:
(1) applying the photosensitive resin composition according to any one of items 1 to 14 onto a substrate to form a photosensitive resin layer on the substrate,
(2) exposing the photosensitive resin layer,
(3) developing the exposed photosensitive resin layer to form a relief pattern, and
(4) subjecting the relief pattern to a heat treatment to form a cured relief pattern.
   [16]

The method for producing a cured relief pattern according to item 15, wherein the heat treatment in the step (4) is a heat treatment at 350° C. or lower.

[17]

A cured film comprising a cured product of the photosensitive resin composition according to any one of items 1 to 14.

[18]

A method for producing a polyimide film, which comprises curing the photosensitive resin composition according to any one of items 1 to 14.

### Advantageous Effects of Invention

According to the present disclosure, it is possible to provide a photosensitive resin composition which has high copper adhesion, suppresses the generation of copper voids at the interface between the copper layer and the resin layer after a high-temperature storage test, and exhibits little copper migration in a b-HAST test. It is also possible to provide a method for producing a cured relief pattern using the photosensitive resin composition, and a method for producing a polyimide film.

### DESCRIPTION OF EMBODIMENTS

Hereinafter, the embodiments of the present disclosure will be described in detail. The present disclosure is not limited to the following embodiments, and can be variously modified and carried out within the gist thereof. Throughout the present disclosure, when a plurality of structures represented by the same reference numerals in the general formula are present in the molecule, they may be the same or different from each other. The upper and lower limit values in each numerical range in the following embodiments can be arbitrarily combined to form any numerical range.

### <Photosensitive Resin Composition>

The photosensitive resin composition of the present disclosure includes (A) a polyimide precursor and/or a polyimide resin, (B) a tetrazole derivative, (C) a photopolymerization initiator, and (D) a solvent.

### (A) Polyimide Precursor

The polyimide precursor (A) is a resin component included in the photosensitive resin composition, and is converted into a polyimide by subjecting to a heat cyclization treatment. The structure of the polyimide precursor (A) is not limited as long as it is a resin which can be used in the photosensitive resin composition, but it is preferable that it is not alkali-soluble. Since the polyimide precursor is not alkali-soluble, high chemical resistance can be obtained.

The polyimide precursor is preferably a polyamide having a structure represented by the following general formula (4):

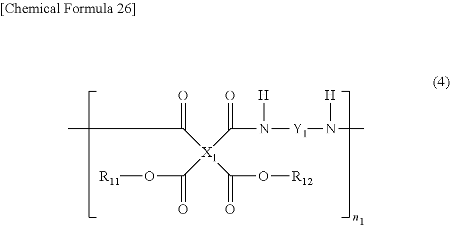

wherein, in formula (4), X₁ is a tetravalent organic group, Y₁ is a divalent organic group, n₁ is an integer of 2 to 150, and R₁₁ and R₁₂ are each independently a hydrogen atom, or a monovalent organic group.

In the general formula (4), at least one of R₁₁ and R₁₂ preferably includes a structural unit represented by the following general formula (5):

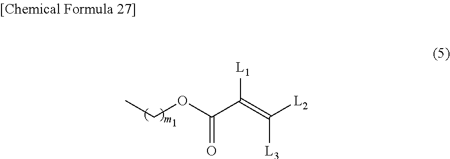

wherein, in formula (5), L₁, L₂ and L₃ are each independently a hydrogen atom, or a monovalent organic group having 1 to 3 carbon atoms, and m₁ is an integer of 2 to 10.

The ratio in which R₁₁ and R₁₂ in the general formula (4) are a hydrogen atom is more preferably 10% or less, still more preferably 5% or less, and yet more preferably 1% or less, based on the total number of mols of R₁₁ and R₁₂. The ratio in which R₁₁ and R₁₂ in the general formula (4) are a monovalent organic group represented by the above general formula (5) is preferably 70% or more, more preferably 80% or more, and still more preferably 90% or more, based on the total number of moles of R₁₁ and R₁₂. From the viewpoints of the photosensitivity and storage stability, the ratio of the hydrogen atom and the ratio of the organic group of the general formula (5) are preferably within the above ranges.

n₁ in the general formula (4) is not limited as long as it is an integer of 2 to 150. From the viewpoint of the photosensitivity and mechanical properties of the photosensitive resin composition, an integer of 3 to 100 is preferable, and an integer of 5 to 70 is more preferable.

In the general formula (4), the tetravalent organic group represented by X₁ is preferably an organic group having 6 to 40 carbon atoms, and more preferably an aromatic group in which a —COOR₁₁ group, a —COOR₁₂ group, and a —CONH— group are located at the ortho-position with each other, or an alicyclic aliphatic group, from the viewpoint of achieving both heat resistance and photosensitivity. Specific examples of the tetravalent organic group represented by X₁ include, but are not limited to, organic groups having 6 to 40 carbon atoms which contain ani aromatic ring, such as groups having structures represented by the following general formula (24):

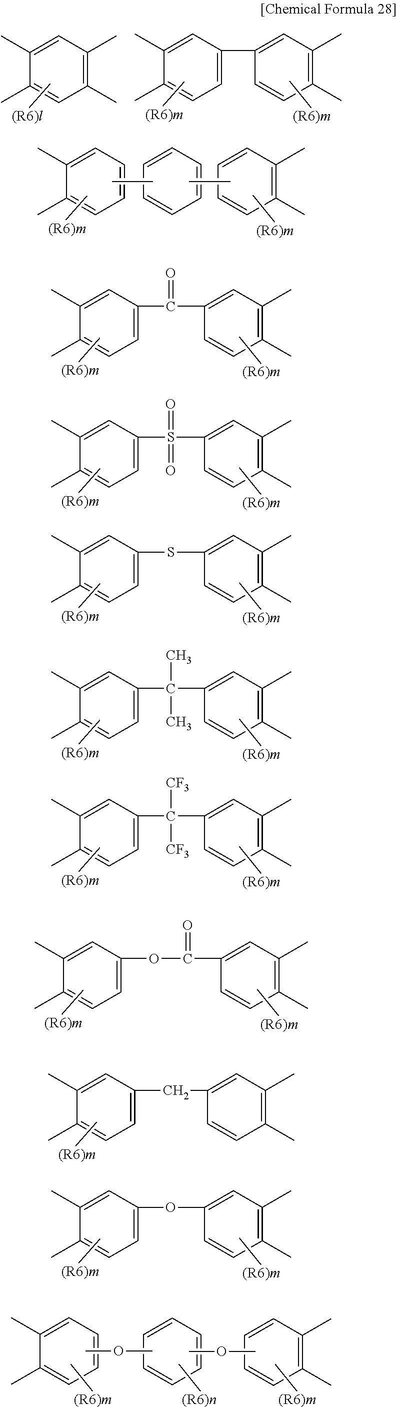

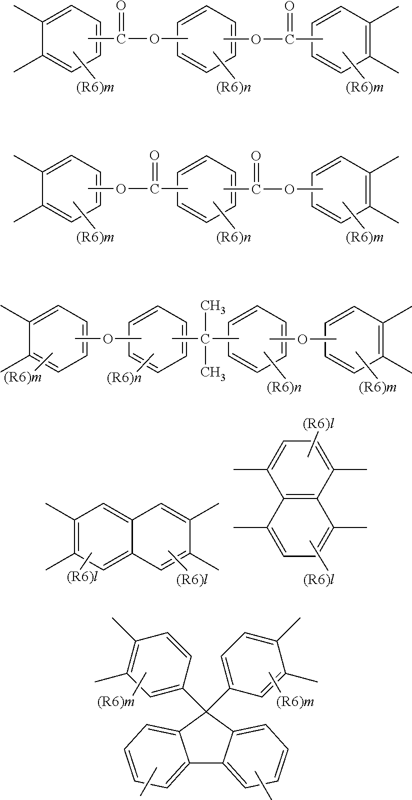

wherein R₆ is at least one selected from the group consisting of a hydrogen atom, a fluorine atom, a C1 to C10 monovalent hydrocarbon group, and a C1 to C10 monovalent fluorine-containing hydrocarbon group, 1 is an integer selected from 0 to 2, m is an integer selected from 0 to 3, and n is an integer selected from 0 to 4. The structure of X₁ may be alone or a combination of two or more thereof. The X₁ group having a structure represented by the above formula (24) is particularly preferable from the viewpoint of achieving both heat resistance and photosensitivity.

Of the structures represented by the above formula (24), the X₁ group is particularly preferably a tetravalent organic group represented by the following formula:

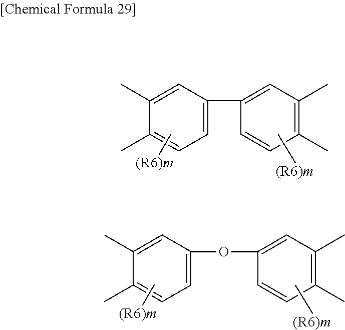

wherein R6 is at least one selected from the group consisting of a fluorine atom, a monovalent hydrocarbon group having 1 to 10 carbon atoms and a monovalent fluorine-containing hydrocarbon group having 1 to 10 carbon atoms, and m is an integer selected from 0 to 3, from the viewpoints of the imidization rate during low-temperature heating, degassing properties, copper adhesion, chemical resistance and the like.

In the above general formula (4), the divalent organic group represented by Y₁ is preferably an aromatic group having 6 to 40 carbon atoms, from the viewpoint of achieving both heat resistance and photosensitivity, and examples thereof include, but are not limited to, structures represented by the following formula (25):

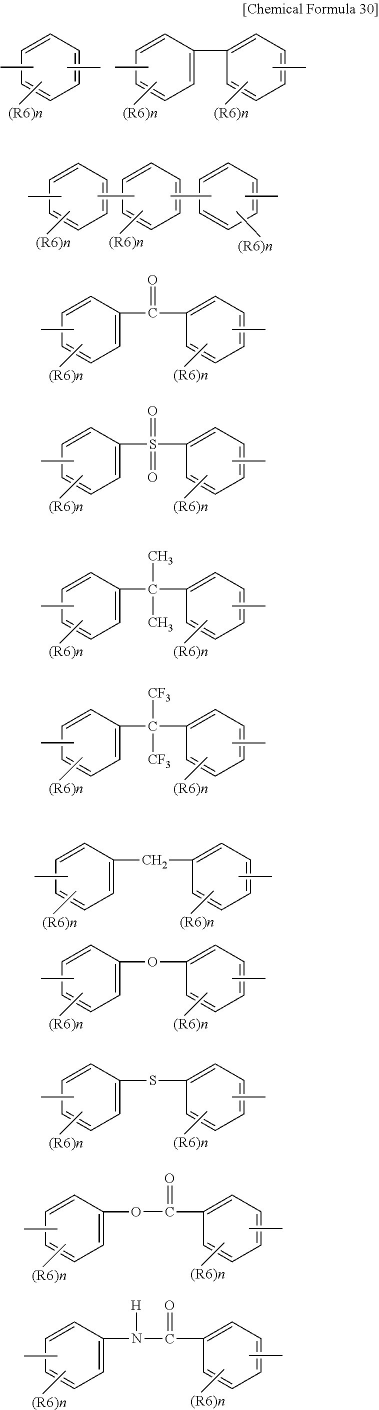

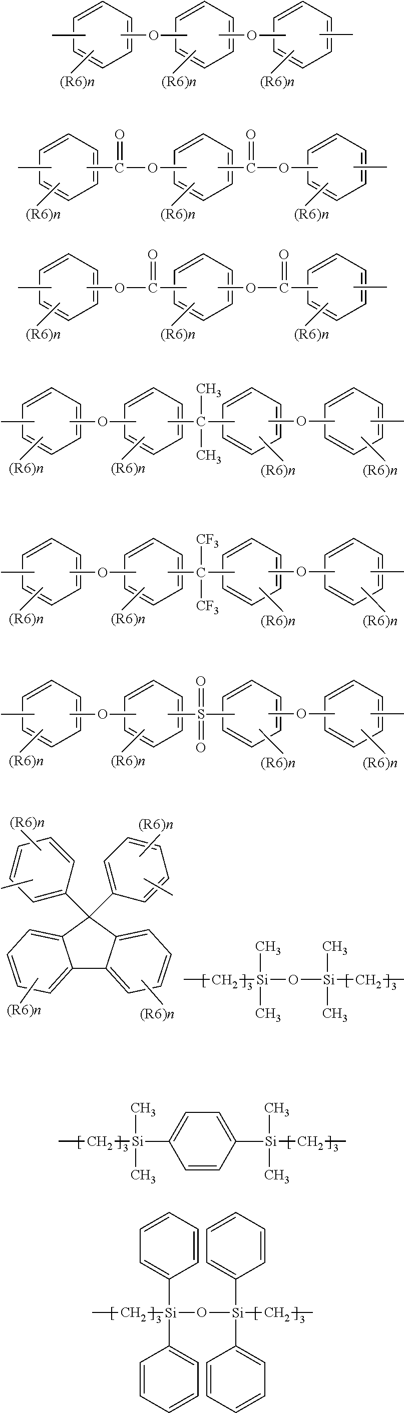

wherein R6 is at least one selected from the group consisting of a hydrogen atom, a fluorine atom, a C1 to C10 monovalent hydrocarbon group, and a C1 to C10 monovalent fluorine-containing hydrocarbon group, and n is an integer selected from 0 to 4. The structure of Y1 may be alone or a combination of two or more thereof. The Y1 group having a structure represented by the above formula (25) is particularly preferable from the viewpoint of achieving both heat resistance and photosensitivity.

Of the structures represented by the above formula (25), the Y₁ group is particularly preferably a divalent group represented by the following formula:

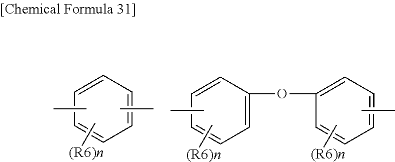

wherein R6 is at least one selected from the group consisting of a fluorine atom, a monovalent hydrocarbon group having 1 to 10 carbon atoms and a monovalent fluorine-containing hydrocarbon group having 1 to 10 carbon atoms, and n is an integer selected from 0 to 4, from the viewpoints of the imidization rate during low-temperature heating, degassing properties, copper adhesion, chemical resistance and the like.

Monovalent organic group having 1 to 3 carbon atoms as for L₁, L₂ and L₃ in the above general formula (5) is, for example, a hydrocarbon group having 1 to 3 carbon atoms, and preferably an alkyl group. L₁ is preferably a hydrogen atom or a methyl group, and L₂ and L₃ are preferably a hydrogen atom from the viewpoint of the photosensitivity. m1 is an integer of 2 or more and 10 or less, and preferably an integer of 2 or more and 4 or less, from the viewpoint of the photosensitivity.

In one embodiment, the polyimide precursor (A) is preferably a polyimide precursor including a structural unit represented by the following general formula (26):

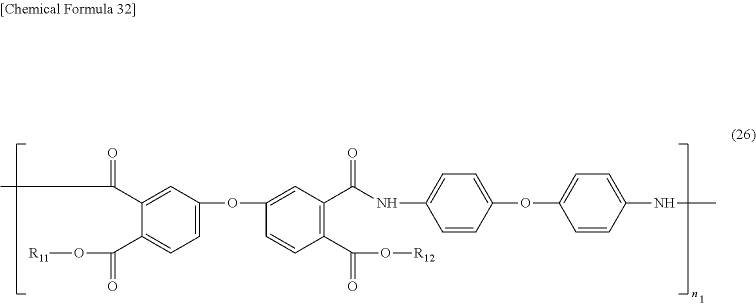

wherein R₁₁, R₁₂, and n₁ are defined above.

In the general formula (26), at least one of R₁₁ and R₁₂ are more preferably a monovalent organic group represented by the above general formula (5). When the polyimide precursor (A) contains a polyimide precursor represented by the general formula (6), the chemical resistance is particularly enhanced.

In one embodiment, the polyimide precursor (A) is preferably a polyimide precursor including a structural unit represented by the following general formula (27):

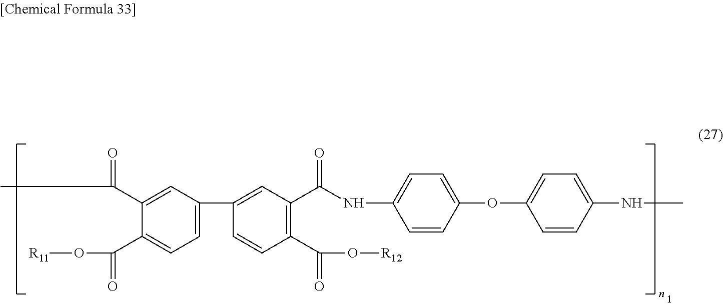

wherein R₁₁, R₁₂, and n₁ are defined above, from the viewpoint of the thermophysical properties.

In the general formula (27), at least one of R₁₁ and R₁₂ is more preferably a monovalent organic group represented by the above general formula (5).

The polyimide precursor (A) including both the structural unit represented by the general formula (26) and the structural unit represented by the general formula (27) tends to exhibit particularly high resolution. For example, the polyimide precursor (A) may contain a copolymer of the structural unit represented by the general formula (26) and the structural unit represented by the general formula (27), or may be a mixture of a polyimide precursor represented by the general formula (26) and a polyimide precursor represented by the general formula (27).

The polyimide precursor (A) is preferably a polyimide precursor including a structural unit represented by the following general formula (28):

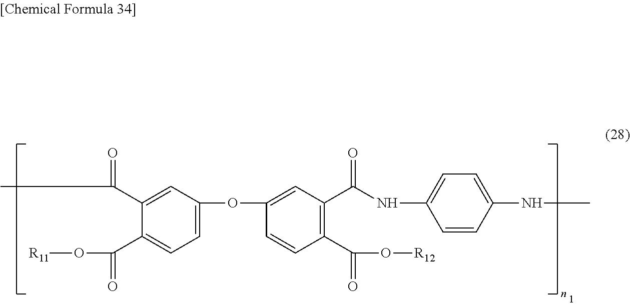

wherein R₁₁, R₁₂, and n₁ are defined above.

The polyimide precursor (A) is preferably a polyimide precursor including a structural unit represented by the following general formula (29):

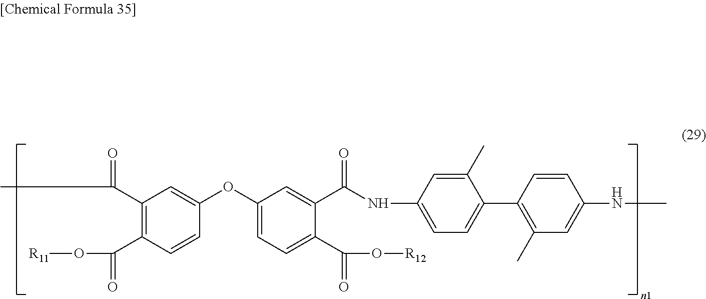

wherein R₁₁, R₁₂, and n₁ are defined above. When the polyimide precursor (A) contains the polyimide precursor represented by the general formula (29), the chemical resistance is particularly enhanced.

The polyimide precursor (A) is contained in an amount of preferably 10 wt. % to 70 wt. %, and more preferably 20 wt. % to 65 wt. %, based on the total weight of the photosensitive resin composition including a solvent.

### (A) Method for Preparing Polyimide Precursor

The polyimide precursor (A) is prepared by first reacting a tetracarboxylic dianhydride having the above-mentioned tetravalent organic group X₁ with an alcohol having a photopolymerizable unsaturated double bond, and optionally with an alcohol having no unsaturated double bond, to prepare a partially esterified tetracarboxylic acid (hereinafter also referred to as acid/ester body), and then the partially esterified tetracarboxylic acid and diamines having the above-mentioned divalent organic group Y1 are subjected to amide polycondensation.

### (Preparation of Acid/Ester Body)

Examples of the tetracarboxylic dianhydride having atetravalent organic group X₁, which is suitably used for the preparation of the polyimide precursor (A), include, but are not limited to, in addition to tetracarboxylic dianhydride represented by the above general formula (24), pyromellitic dianhydride (PMDA), 4,4′-oxydiphthalic dianhydride (ODPA), benzophenone-3,3′,4,4′-tetracarboxylic dianhydride, biphenyl-3,3′,4,4′-tetracarboxylic dianhydride (BPDA), diphenylsulfone-3,3′,4,4′-tetracarboxylic dianhydride, diphenylmethane-3,3′,4,4′-tetracarboxylic dianhydride, 2,2-bis(3,4-phthalic anhydride)propane, 2,2-bis(3,4-phthalic anhydride)-1,1,1,3,3,3-hexafluoropropane and the like. Of these, preferred examples of the tetracarboxylic dianhydride include pyromellitic dianhydride (PMDA), 4,4′-oxydiphthalic dianhydride (ODPA), and biphenyl-3,3′,4,4′-tetracarboxylic dianhydride (BPDA). Of course, these can be used alone, or two or more thereof may be mixed and used.

Examples of the alcohol having a photopolymerizable unsaturated double bond, which is suitably used for the preparation of the polyimide precursor (A), include 2-acryloyloxyethyl alcohol, 1-acryloyloxy-3-propyl alcohol, 2-acrylamidoethyl alcohol, methylol vinyl ketone, 2-hydroxyethyl vinyl ketone, 2-hydroxy-3-methoxypropyl acrylate, 2-hydroxy-3-butoxypropyl acrylate, 2-hydroxy-3-phenoxypropyl acrylate, 2-hydroxy-3-butoxypropyl acrylate, 2-hydroxy-3-t-butoxypropyl acrylate, 2-hydroxy-3-cyclohexyloxypropyl acrylate, 2-methacryloyloxyethyl alcohol, 1-methacryloyloxy-3-propyl alcohol, 2-methacrylamidoethyl alcohol, methylol vinyl ketone, 2-hydroxyethyl vinyl ketone, 2-hydroxy-3-methoxypropyl methacrylate, 2-hydroxy-3-butoxypropyl methacrylate, 2-hydroxy-3-phenoxypropyl methacrylate, 2-hydroxy-3-butoxypropyl methacrylate, 2-hydroxy-3-t-butoxypropyl methacrylate, 2-hydroxy-3-cyclohexyloxypropyl methacrylate and the like.

The photopolymerizable alcohol having an unsaturated double bond may be used after partially mixing with an alcohol having no unsaturated double bond, such as methanol, ethanol, n-propanol, isopropanol, n-butanol, tert-butanol, 1-pentanol, 2-pentanol, 3-pentanol, neopentyl alcohol, 1-heptanol, 2-heptanol, 3-heptanol, 1-octanol, 2-octanol, 3-octanol, 1-nonanol, triethylene glycol monomethyl ether, triethylene glycol monoethyl ether, tetraethylene glycol monomethyl ether, tetraethylene glycol monoethyl ether, and benzyl alcohol.

A non-photosensitive polyimide precursor prepared by reacting with only an alcohol having no saturated double bond may be mixed with the photosensitive polyimide precursor and used as the polyimide precursor. From the viewpoint of the resolution, the amount of the non-photosensitive polyimide precursor is preferably 200 parts by weight or less based on 100 parts by weight of the photosensitive polyimide precursor. By dissolving the above-mentioned suitable tetracarboxylic dianhydride and alcohol in a solvent mentioned later in the presence of a basic catalyst such as pyridine, followed by stirring and mixing at a temperature of 20 to 50° C. for 4 to 10 hours, the esterification reaction of an acid anhydride proceeds, and thus the desired acid/ester body can be obtained.

### (Preparation of Polyimide Precursor)

To the acid/ester body (typically, a solution of a solvent mentioned later), an appropriate dehydration condensing agent, for example, dicyclohexylcarbodiimide, 1-ethoxycarbonyl-2-ethoxy-1,2-dihydroquinoline, 1,1-carbonyldioxy-di-1,2,3-benzotriazole, N,N′-disuccinimidyl carbonate or the like is charged under ice cooling to convert the acid/ester body into a polyacid anhydride, and to this, a diamine having a divalent organic group Y₁ separately dissolved or dispersed in a solvent is added dropwise to carry out amide polycondensation, and thus the desired polyimide precursor can be obtained. Alternatively, the desired polyimide precursor can be obtained by reacting the acid/ester body with a diamine compound in the presence of a base such as pyridine after acid chloridization of an acid moiety using thionyl chloride.

Examples of the diamine having a divalent organic group Y₁ include, but are not limited to, in addition to a diamine having a structure represented by the above general formula (21), p-phenylenediamine (1,4-phenylenediamine (pPD)), m-phenylenediamine, 4,4′-oxydianiline (ODA), 3,4′-diaminodiphenyl ether, 3,3′-diaminodiphenyl ether, 4,4′-diaminodiphenylsulfide, 3,4′-diaminodiphenylsulfide, 3,3′-diaminodiphenylsulfide, 4,4′-diaminodiphenylsulfone, 3,4′-diaminodiphenylsulfone, 3,3′-diaminodiphenylsulfone, 4,4′-diaminobiphenyl, 3,4′-diaminobiphenyl, 3,3′-diaminobiphenyl, 4,4′-diaminobenzophenone, 3,4′-diaminobenzophenone, 3,3′-diaminobenzophenone, 4,4′-diaminodiphenylmethane, 3,4′-diaminodiphenylmethane, 3,3′-diaminodiphenylmethane, 1,4-bis(4-aminophenoxy)benzene (TPE-Q), 1,3-bis(4-aminophenoxy)benzene, 1,3-bis(3-aminophenoxy)benzene (APB), bis[4-(4-aminophenoxy)phenyl]sulfone, bis[4-(3-aminophenoxy)phenyl]sulfone, 4,4-bis(4-aminophenoxy)biphenyl, 4,4-bis(3-aminophenoxy)biphenyl, bis[4-(4-aminophenoxy)phenyl]ether, bis[4-(3-aminophenoxy)phenyl]ether, 1,4-bis(4-aminophenyl)benzene, 1,3-bis(4-aminophenyl)benzene, 9,10-bis(4-aminophenyl)anthracene, 2,2-bis(4-aminophenyl)propane, 2,2-bis(4-aminophenyl)hexafluoropropane, 2,2-bis[4-(4-aminophenoxy)phenyl]propane, 2,2-bis[4-(4-aminophenoxy)phenyl]hexafluoropropane (HFBAPP), 1,4-bis(3-aminopropyldimethylsilyl)benzene, ortho-tolidine sulfone and 9,9-bis(4-aminophenyl)fluorene (BAFL); and those in which a part of hydrogen atoms on the benzene ring thereof is substituted with a methyl group, an ethyl group, a hydroxymethyl group, a hydroxyethyl group or halogen, such as 3,3′-dimethyl-4,4′-diaminobiphenyl, 2,2′-dimethyl-4,4′-diaminobiphenyl, 3,3′-dimethyl-4,4′-diaminodiphenylmethane, 2,2′-dimethyl-4,4′-diaminodiphenylmethane, 3,3′-dimethoxy-4,4′-diaminobiphenyl, 3,3′-dichloro-4,4′-diaminobiphenyl, and mixtures thereof. Preferred examples of the diamine include 4,4′-oxydianiline (ODA), 2,2′-dimethylbiphenyl-4,4′-diamine (m-TB), and 1,4-phenylenediamine (pPD). These can be used alone, or two or more thereof may be mixed and used.

After completion of the amide polycondensation reaction, the water absorption by-products of the dehydration condensing agent present in the reaction solution are filtered as necessary, and then a poor solvent such as water, an aliphatic lower alcohol, or a mixed liquid thereof is charged into the obtained polymer component to precipitate the polymer component, and then a redissolution or reprecipitation process is repeated, whereby the polymer is purified and vacuum-dried to isolate the target polyimide precursor. In order to improve the degree of purification, a solution of the polymer may be passed through a column filled with an anion and/or cation exchange resin swollen with an appropriate organic solvent to remove ionic impurities.

The molecular weight of the polyimide precursor (A) is preferably 8,000 to 150,000, and more preferably 9,000 to 50,000, when measured by polystyrene-equivalent weight-average molecular weight by gel permeation chromatography. When the weight-average molecular weight is 8,000 or more, satisfactory mechanical physical properties are exhibited, and when the weight-average molecular weight is 150,000 or less, satisfactory dispersibility in a developer and satisfactory resolution of a relief pattern thereof are exhibited. Tetrahydrofuran and N-methyl-2-pyrrolidone are recommended as developing solvents for gel permeation chromatography. The weight-average molecular weight is also determined from a calibration curve prepared using standard monodisperse polystyrene. As the standard monodisperse polystyrene, it is recommended to select from the organic solvent-based standard sample STANDARD SM-105 manufactured by Showa Denko K.K.

### (A) Polyimide Resin

The photosensitive resin composition of the present disclosure may include a polyimide resin (A) together with or instead of the polyimide precursor (A).

The polyimide resin (A) does not generate any resin-derived elimination components, thus making it possible to suppress the cure shrinkage of the photosensitive resin composition. Therefore, it is possible to obtain a photosensitive resin composition which has a higher cured remaining film rate and improved flatness after curing, as compared with the polyimide precursor.

The polyimide resin (A) may have a polymerizable group in the side chain. However, from the viewpoint of the elongation and storage stability of the cured film, it is preferable that the polyimide resin does not have a polymerizable group in the side chain. It is preferable that the polyimide resin is substantially free from a polyamic acid or polyamic acid ester structure. In the present disclosure, “substantially free” means, for example, that the imidization rate of the polyimide resin is 90% or more, and preferably 95% or more.

The imidization rate of the polyimide resin can be measured by a known method, but is calculated by the following method in the present disclosure. First, the infrared absorption spectrum of the polyimide resin is measured to confirm the presence of absorption peaks of the imide structure (near 1,780 cm⁻¹ and 1,377 cm⁻¹). Next, the polyimide resin is heat-treated at 350° C. for 1 hour, and the infrared absorption spectrum after the heat treatment is measured. The peak intensity near 1,377 cm⁻¹ is compared with the peak intensity before the heat treatment to calculate the imidization rate of the polyimide resin.

From the viewpoints of the solubility in a solvent and flatness during coating, it is preferable that the polyimide resin (A) has a structure represented by the general formula (4′). This structure is suitable for a solvent-developable type photosensitive resin composition.

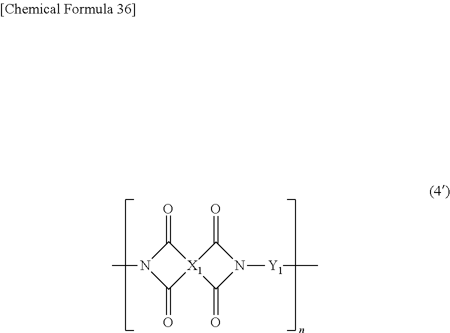

In formula (4′), X₁ is a tetravalent organic group, Y₁ is a divalent organic group, and n is an integer of 1 to 150.

X₁ is a tetravalent organic group, and is not particularly limited as long as it is a structure derived from a known tetracarboxylic dianhydride. From the viewpoints of high copper adhesion of the cured film, suppression of copper voids after a high-temperature storage test, suppression of copper migration in a b-HAST test, excellent elongation and chemical resistance, and solubility in a solvent mentioned later, it is preferable that the cured film has at least one structure represented by the following formulas (6) to (14).

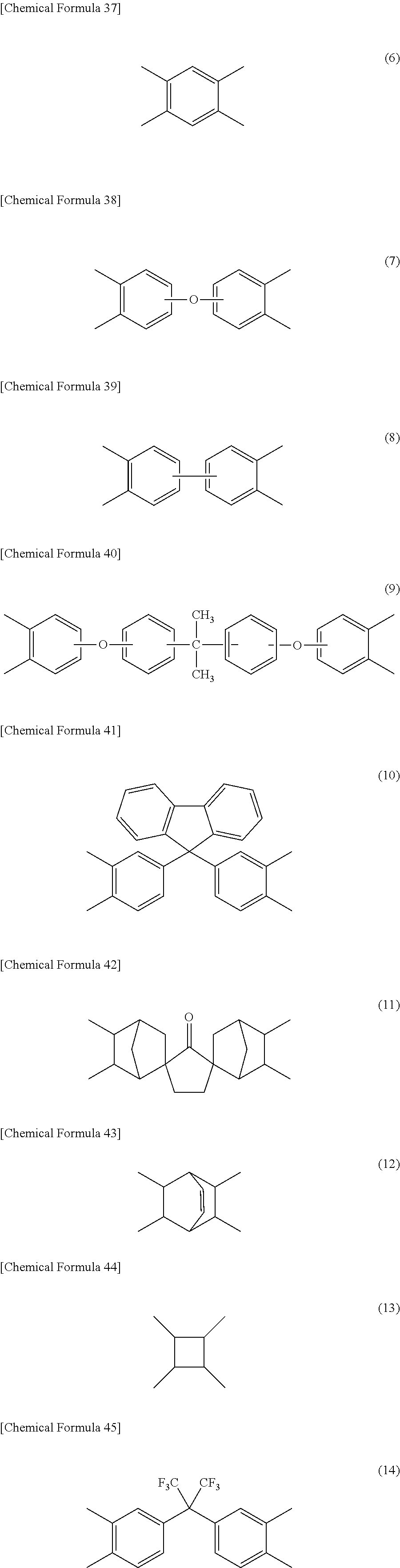

From the viewpoints of suppression of copper voids after a high-temperature storage test of a cured film obtained from the photosensitive resin composition of the present disclosure, suppression of copper migration in a b-HAST test, and elongation and chemical resistance, it is preferable that X₁ has at least one structure represented by formulas (6) to (13). Furthermore, from the viewpoint of the heat resistance of a cured film obtained from the photosensitive resin composition of the present disclosure, it is more preferable that X₁ has at least one structure represented by formulas (6) to (8) and (10) to (13). Since X₁ has particularly excellent coating film uniformity and cured film elongation of the photosensitive resin composition of the present disclosure, it is particularly preferable that X₁ has at least one structure represented by formulas (6) and (11) to (13).

Y₁ in formula (4′) is a divalent organic group, and is not particularly limited as long as it is a structure derived from a known diamine. From the viewpoints of high copper adhesion of the cured film, suppression of copper voids after a high-temperature storage test, suppression of copper migration in a b-HAST test, excellent elongation and chemical resistance, and solubility in a solvent, it is preferable to have at least one structure represented by the following formulas (15) to (23).

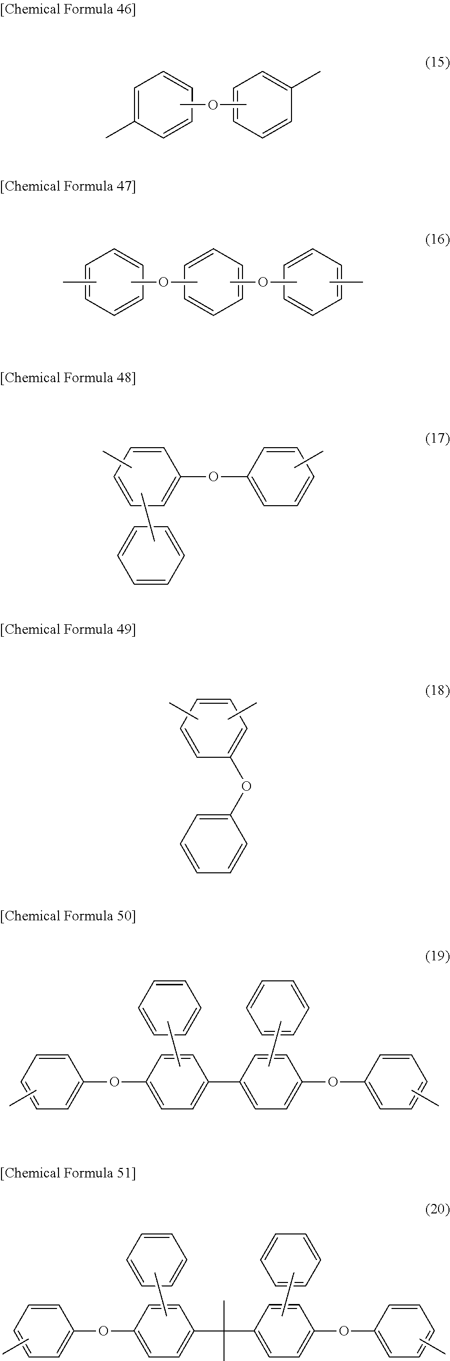

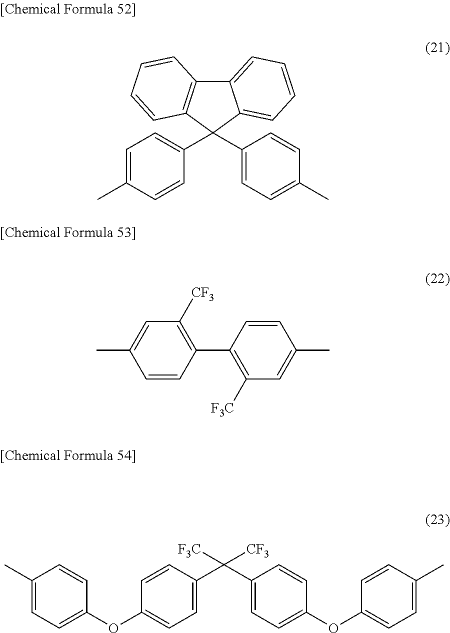

From the viewpoints of suppression of copper voids after a high-temperature storage test of a cured film obtained from the photosensitive resin composition of the present disclosure, suppression of copper migration in a b-HAST test, and elongation and chemical resistance, it is preferable that Y₁ has at least one structure represented by formulas (15) to (21). Furthermore, from the viewpoint of the mechanical properties of the cured film obtained from the photosensitive resin composition of the present disclosure, it is more preferable that Y₁ has at least one structure represented by formulas (15) to (20). Since Y₁ provides particularly excellent coating film uniformity and cured film elongation of the negative photosensitive resin composition of the present disclosure, it is particularly preferable that Y₁ has at least one structure represented by formulas (17) to (20). The excellent solubility of the structures represented by formulas (17) to (20) in a solvent is due to the fact that these structures have a pendant phenyl structure.

In formula (4′), n is an integer of 2 to 150, preferably an integer of 3 to 100, and more preferably an integer of 5 to 70. It is preferable that n is an integer satisfying the weight-average molecular weight of the polyimide resin (A) mentioned later.

From the viewpoint of the solubility in a solvent mentioned later, it is preferable that an end of the polyimide resin (A), preferably an end of the main chain of the polyimide resin (A), has at least one structure selected from the group consisting of an acid anhydride group, a carboxyl group, an amino group, and the following general formulas (30) to (32):

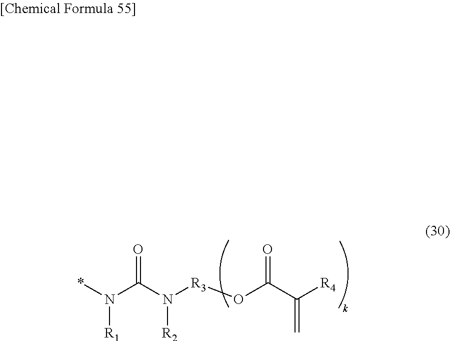

wherein, in formula (30), R₁ and R₂ are each independently selected from a hydrogen atom, and a monovalent organic group having 1 to 3 carbon atoms, R₃ is an organic group having 1 to 20 carbon atoms which may contain a heteroatom, k is an integer of 1 to 2, R₄ is a hydrogen atom, and an organic group having 1 to 4 carbon atoms, and * represents a bonding site with an end of the polyimide resin (A):

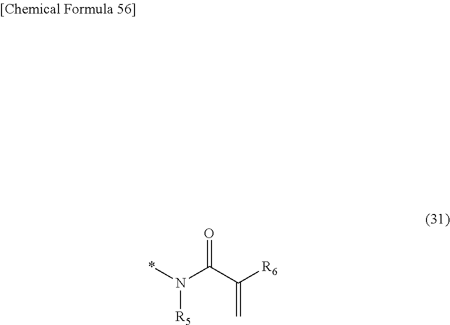

wherein, in formula (31), R₅ and R₆ are each independently a hydrogen atom, and a monovalent organic group having 1 to 3 carbon atoms, and * represents a bonding site with an end of the polyimide resin (A), and:

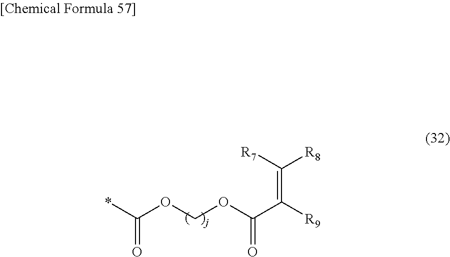

wherein, in formula (32), R₇, R₈ and R₉ are each independently a hydrogen atom or a monovalent organic group having 1 to 3 carbon atoms, j is an integer of 2 to 10, and * represents a bonding site with an end of the polyimide resin (A).

It is preferable that the acid anhydride group is derived from a tetracarboxylic anhydride as the raw material, the carboxyl group is formed by ring-opening the above-mentioned acid anhydride group, and the amino group is derived from a diamine as the raw material. More specific examples of the case where the end of the polyimide resin (A) is a structure represented by the general formula (30) include structures represented by the following formulas (33) to (36):

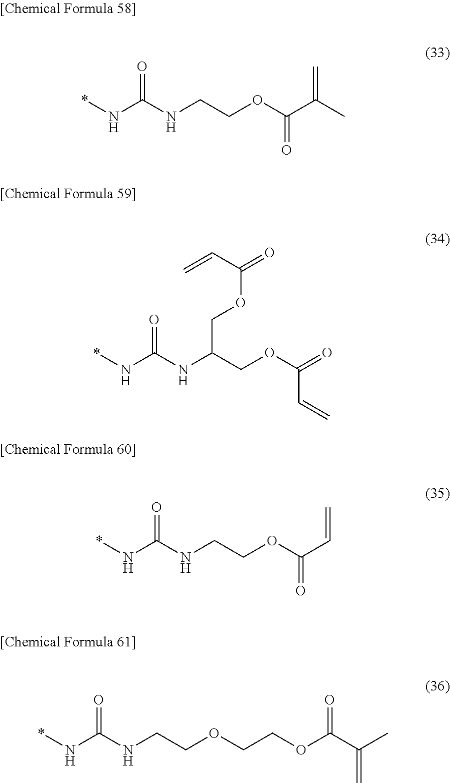

wherein * represents a bonding site with an end of the polyimide resin (A).

More specific examples of the structure represented by the general formula (31) include structures represented by the following formulas (37) and (38):

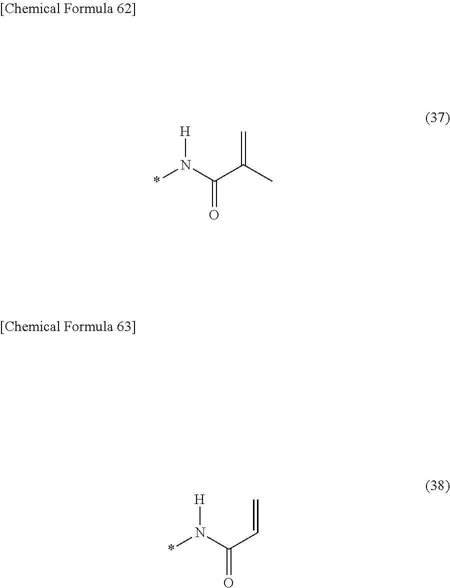

wherein * represents a bonding site with an end of the polyimide resin (A).

More specific examples of the structure represented by the general formula (32) include structures represented by the following formulas (39) to (42):

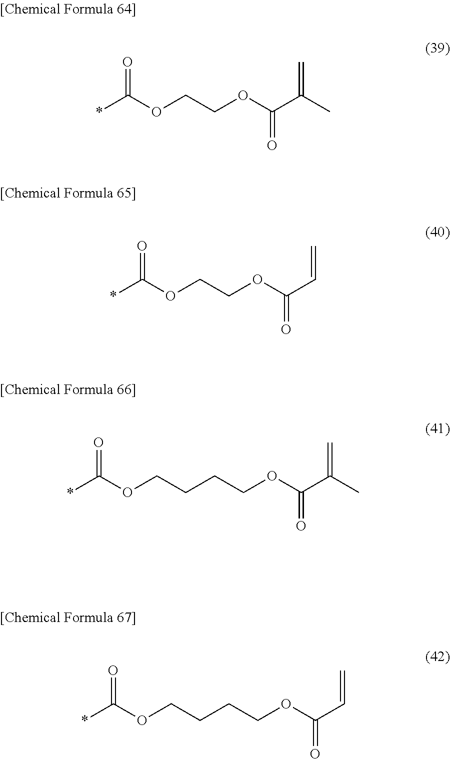

wherein * represents a bonding site with an end of the polyimide resin (A).

From the viewpoints of high copper adhesion of the cured film, suppression of copper voids after a high-temperature storage test, suppression of copper migration in a b-HAST test, elongation, chemical resistance, and solubility in a solvent, it is preferable that X₁ in the general formula (4′) is any of the structures represented by the general formulas (6) to (14), and Y₁ is any of the structures represented by the general formulas (15) to (23).

The weight-average molecular weight (Mw) of the polyimide resin (A) is not particularly limited as long as it can be dissolved in a solvent. From the viewpoints of the film physical properties of the cured film and copper adhesion, the weight-average molecular weight of the polyimide resin (A) is preferably 5,000 or more and 100,000 or less. From the viewpoint of the mechanical properties, the lower limit of the weight-average molecular weight of the polyimide resin (A) is more preferably 6,000 or more, and still more preferably 8,000 or more. The upper limit of the weight-average molecular weight of the polyimide resin (A) is more preferably 50,000 or less, and particularly preferably 30,000 or less, from the viewpoints of solubility in a solvent and flatness during coating.

The molecular weight distribution (Mw/Mn) of the polyimide resin (A) is preferably 1.0 or more and 2.0 or less. From the viewpoint of the production efficiency, the lower limit of the molecular weight distribution of the polyimide resin (A) is more preferably 1.15 or more, and still more preferably 1.25 or more. The upper limit of the molecular weight distribution of the polyimide resin (A) is more preferably 1.8 or less, and still more preferably 1.6 or less, from the viewpoint of the resolution.

The polyimide resin (A) is included in an amount of preferably 10 wt. % to 70 wt. %, and more preferably 20 wt. % to 65 wt. %, based on the total weight of the photosensitive resin composition including the solvent.

### (A) Method for Preparing Polyimide Resin (A)

The polyimide resin (A) is obtained by subjecting a polyamic acid, which is obtained by reacting a tetracarboxylic dianhydride with a diamine, to dehydration ring-closure to undergo imidization.

The method for dehydration ring-closure of the polyamic acid is not limited, but examples thereof include a thermal imidization method in which the polyamic acid is heated at a high temperature to undergo dehydration ring-closure, and a chemical imidization method in which an acetic anhydride and a tertiary amine as dehydration reducing agents are added to undergo dehydration ring-closure.

The temperature in the thermal imidization method is not particularly limited, but the lower limit thereof is preferably 150° C. or higher, and more preferably 160° C. or higher, from the viewpoint of promoting the ring-closure reaction. On the other hand, from the viewpoint of suppressing side reactions, the upper limit thereof is preferably 200° C. or lower, and more preferably 180° C.

The tetracarboxylic dianhydride is not particularly limited, but specific examples thereof include pyromellitic anhydride (PMDA), 4,4′-oxydiphthalic anhydride (ODPA), 3,4′-oxydiphthalic anhydride, 4,4′-biphthalic dianhydride (BPDA), 3,4′-biphthalic dianhydride, 4,4′-(4,4′-isopropylidenediphenoxy)diphthalic anhydride (BPADA), 9,9-bis(3,4-dicarboxyphenyl)fluorene dianhydride (BPAF), norbornane-2-spiro-α-cyclopentanone-α′-spiro-2″-norbornane-5,5″,6,6″-tetracarboxylic dianhydride (CpODA), bicyclo[2.2.2]oct-7-ene-2,3,5,6-tetracarboxylic dianhydride (BCD), 1,2,3,4-cyclobutane tetracarboxylic anhydride (CBDA), and 4,4′-(hexafluoroisopropylidene)diphthalic anhydride (6FDA). Of these, the tetracarboxylic dianhydride is preferably bicyclo[2.2.2]oct-7-ene-2,3,5,6-tetracarboxylic dianhydride (BCD), 1,2,3,4-cyclobutanetetracarboxylic dianhydride (CBDA), and 4,4′-(hexafluoroisopropylidene)diphthalic dianhydride (6FDA).

The diamine is not particularly limited, but specific examples thereof include 4,4′-diaminodiphenyl ether (DADPE), 3,4′-diaminodiphenyl ether, 1,3-bis(3-aminophenoxy)benzene (APB), 1,4-bis(4-aminophenoxy)benzene (TPE-Q), 2-phenoxybenzene-1,4-diamine (PND), 9,9-bis(4-aminophenyl)fluorene (BAFL), 6-(4-aminophenoxy)biphenyl-3-amine (PDPE), 3,3′-diphenyl-4,4′-bis(4-aminophenoxy)biphenyl (APBP-DP), 2,2-bis[3-phenyl-4-(4-aminophenoxy)phenyl]propane (DAOPPA), 2,2′-dimethylbenzidine, 2,2′-bis(trifluoromethyl)benzidine (TFMB), 2,2-bis[4-(4-aminophenoxy)phenyl]hexafluoropropane (HFBAPP), and 2-(methacryloyloxy)ethyl-3,5-diaminobenzoate (MAEDAB). Of these, the diamine is preferably 6-(4-aminophenoxy)biphenyl-3-amine (PDPE) and 9,9′-bis(4-aminophenyl)fluorene (BAFL).

In the case where the ends of the polyimide resin (A) are an acid anhydride group, a carboxyl group and an amino group, the polyimide resin (A) is a polyimide resin obtained by subjecting a polyamic acid, which is obtained by reacting a tetracarboxylic dianhydride with a diamine, to dehydration ring-closure to undergo imidization. The acid anhydride group, carboxyl group and amino group at the end of the polyimide resin (A) may be reacted with a prescribed compound to form the ends into structures represented by the above general formulas (30) to (32).

The polyimide resin (A) whose end is a structure represented by the general formula (30) can be obtained, for example, by reacting an amino group at the polyimide end with an isocyanate-based compound. Specific examples of the isocyanate-based compound include 2-methacryloyloxyethyl isocyanate (2-isocyanatoethyl methacrylate: MOI), 2-acryloyloxyethyl isocyanate, 1,1-(bisacryloyloxymethyl)ethyl isocyanate, and 2-(2-methacryloyloxyethyloxy)ethyl isocyanate. The method for reacting the isocyanate-based compound is not particularly limited, but it is possible to react with amino groups of the dehydrated ring-dosed polyimide by adding the isocyanate-based compound to the dehydrated ring-closed polyimide solution, followed by stirring at room temperature.

The polyimide resin (A) whose end is a structure represented by the general formula (31) can be obtained, for example, by reacting an amino group at the polyimide end with a chloride-based compound. Examples of the chloride-based compound include acryloyl chloride and methacryloyl chloride. The method for reacting the chloride-based compound is not particularly limited, but it is possible to react with amino groups of the dehydrated ring-closed polyimide by ice-cooling the dehydrated ring-dosed polyimide solution and adding dropwise the chloride-based compound.

The polyimide resin (A) whose end is represented by the general formula (32) can be obtained, for example, by reacting an acid anhydride group and a carboxyl group at the polyimide end with an alcohol-based compound. Examples of alcohol-based compound include 2-hydroxyethyl methacrylate (2-hydroxyethyl methacrylate: HEMA), 2-hydroxyethyl acrylate, 4-hydroxyethyl methacrylate, and 4-hydroxyethyl acrylate. The method for reacting the alcohol-based compound is not particularly limited, but the acid anhydride group and the carboxyl group of the dehydrated ring-closed polyimide can be reacted with the alcohol-based compound using a condensing agent such as N,N′-dicyclohexylcarbodiimide (DCC) or an esterification catalyst such as p-toluenesulfonic acid.

In the production of the polyimide resin (A), a reaction solvent may be used to efficiently carry out the reaction in a homogeneous system. The reaction solvent is not particularly limited as long as it can uniformly dissolve or suspend the tetracarboxylic dianhydride, the diamine, and the compound having a polymerizable functional group at the end. Examples of the reaction solvent include y-butyrolactone (GBL), dimethyl sulfoxide, N,N-dimethylacetoacetamide, 1,3-dimethyl-2-imidazolidinone, 3-methoxy-N,N-dimethylpropanamide, 3-butoxy-N,N-dimethylpropanamide, N,N-dimethylformamide, N-methyl-2-pyrrolidone, N-ethyl-2-pyrrolidone, and N,N-dimethylacetamide.

When a thermal imidization method is used in the production of the polyimide resin (A), an azeotropic solvent may be used to promote the imidization reaction. The azeotropic solvent is not particularly limited as long as it is a solvent which azeotropes with water, and examples thereof include toluene, ethyl acetate, N-dicyclohexylpyrrolidone, orthodichlorobenzene, xylene, and benzene.

The polyimide resin (A) may be purified by a method mentioned in PTL 2 (JP 2012-194520 A) or the like. Examples of the purification method include (A) a method in which a polyimide resin solution is added dropwise in water and an unreacted substance is removed by reprecipitation, a method in which a condensing agent insoluble in a reaction solvent is removed by filtration, and a method in which a catalyst is removed by an ion exchange resin. After purification, the polyimide resin (A) may be dried by a known method and isolated in a powder state.

### (B) Tetrazole Derivative

The tetrazole derivative (B) has a pKa of 1.3 to 4.1, or it is represented by formula (1) or (2) mentioned later, or has a polar surface area (tPSA) of 81 or more and 200 or less, and has a combination of one or more of these characteristics. By including such a tetrazole derivative (B), copper adhesion and copper migration suppression effect can be obtained. It is assumed that copper voids are generated as a result of the progression of copper migration, so that the suppression of copper migration also exerts the effect on the suppression of copper voids.

In one embodiment, the tetrazole derivative (B) has an acid dissociation constant (pKa) of 1.3 or more and 4.1 or less. From the viewpoints of the adhesion to copper and copper migration, the pKa is preferably 2.0 or more and 3.6 or less. The reason why the above effects are exerted by using such a tetrazole derivative (B) is not clear and, although not limited to theory, the inventors believe it to be as follows. That is, it is believed that the tetrazole derivative exerts its effect by coordinating to copper of the substrate, and in this case, it is presumed that if the pKa of the tetrazole derivative is 4.1 or less, the interaction with the resin is enhanced, leading to an improvement in copper adhesion. On the other hand, if the pKa of the tetrazole derivative is 1.3 or more, the interaction is not too strong, and it is believed that copper migration can be suppressed. It is therefore presumed that the tetrazole derivative has an appropriate acidity, which allows both adhesion to copper and prevention of copper migration to be achieved. For pKa, values calculated using Advanced Chemistry Software V11.02 (1994-2018 ACD/Labs) were used.

Examples of the tetrazole derivative (B) having an acid dissociation constant (pKa) of 1.3 or more and 4.1 or less include, but are not limited to, 1H-tetrazole-5-carboxylic acid, 1H-tetrazole-5-acetic acid, ethyl 1H-tetrazole-5-carboxylate, methyl 1H-tetrazole-5-acetate, 1H-tetrazole-5-propionic acid, 2-[4-(1H-1,2,3,4-tetrazol-5-yl)phenyl]acetic acid, 2-(2H-tetrazol-5-yl)butanedioic acid, 2,2-bis(2-2H-tetrazol-5-yl)ethyl)propanedioic acid, and 4-(1H-tetrazol-5-yl)benzoic acid. Of these, from the viewpoints of copper adhesion and copper migration, 1H-tetrazole-5-carboxylic acid, 1H-tetrazole-5-acetic acid, and 4-(1H-tetrazol-5-yl)benzoic acid are preferable, and 1H-tetrazole-5-acetic acid is more preferable. When these compounds are added to the resin composition, they may be in the form of a hydrate.

In one embodiment, the tetrazole derivative (B) is represented by the following formula (1) or (2):

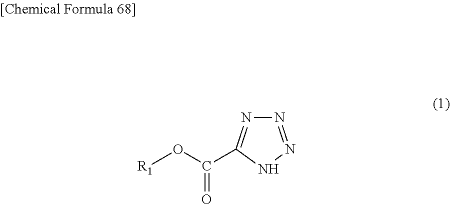

wherein, in formula (1), R₁ is a hydrogen atom, or a monovalent organic group selected from the group consisting of an alkyl group having 1 to 10 carbon atoms and an aryl group having 6 to 10 carbon atoms, and hydrogen atoms of the alkyl group and the aryl group may or may not be each independently substituted with at least one substituent selected from the group consisting of a halogen atom, a hydroxyl group, an alkoxysilyl group and an amino group:

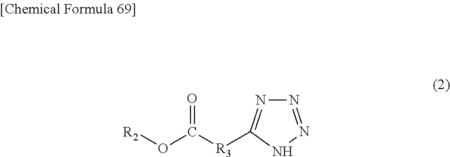

wherein, in formula (2), R₂ is a hydrogen atom, or a monovalent organic group selected from the group consisting of an alkyl group having 1 to 10 carbon atoms and an aryl group having 6 to 10 carbon atoms, R₃ is an alkylene group having 1 to 10 carbon atoms, and hydrogen atoms of the alkyl group, the aryl group and the alkylene group may or may not be each independently substituted with at least one substituent selected from the group consisting of a halogen atom, a hydroxyl group, an alkoxysilyl group and an amino group.

When the tetrazole derivative (B) contains a compound represented by the above formula (1) or (2), excellent copper adhesion, copper migration suppression effect, and copper void suppression effect can be obtained. The reason for this is unclear, and although not bound by theory, it is believed that the unshared electron pair associated with the nitrogen atom in the tetrazole acts on copper and is unevenly distributed at the copper interface, and the constituent atoms of the carboxylic acid and ester can form hydrogen bonds with the polyimide precursor, and thus the resin interacts with copper, leading to an improvement in copper adhesion. It is also believed that the uneven distribution of the tetrazole derivative at the copper interface strongly suppresses the oxidation reaction at the copper interface, thus making it possible to suppress copper migration and copper voids. When R₃ in the general formula (2) has 1 to 10 carbon atoms, the boiling point of the molecule is higher than that of the compound of the general formula (1), so that it is less likely to volatilize during pre-baking when coating the substrate and can remain in the film. It is also more likely to move within the film and be unevenly distributed at the interface, and thus it is presumed to be more effective in improving copper adhesion and suppressing copper voids.

Furthermore, particularly from the viewpoint of copper adhesion, it is preferable that the tetrazole derivative (B) contains a compound represented by the following general formula (3):

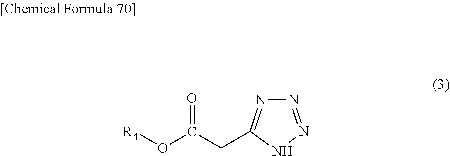

wherein R₄ is a hydrogen atom, or a monovalent organic group selected from the group consisting of an alkyl group having 1 to 10 carbon atoms and an aryl group having 6 to 10 carbon atoms, and hydrogen atoms of the alkyl group and the aryl group may or may not be each independently substituted with at least one substituent selected from the group consisting of a halogen atom, a hydroxyl group, an alkoxysilyl group and an amino group.

The alkyl group having 1 to 10 carbon atoms as for R₁, R₂ and R₄ in the general formulas (1) to (3) may be branched or linear. Preferred are alkyl groups having 1 to 5 carbon atoms, such as a methyl group, an ethyl group, and a propyl group. Examples of the aryl group having 6 to 10 carbon atoms as for R₁, R₂ and R₄ in the general formulas (1) to (3) include a phenyl group, a tolyl group, a xylyl group, and a naphthyl group. The alkylene group having 1 to 10 carbon atoms as for R₃ in the general formula (3) may be branched or linear. Preferred are alkylene groups having 1 to 5 carbon atoms, such as a methylene group, an ethylene group, and a propylene group. Hydrogen atoms of these organic groups may or may not be independently substituted with at least one substituent selected from the group consisting of a halogen atom, a hydroxyl group, an alkoxysilyl group, and an amino group. However, when an alkoxysilyl group is present, the number of carbon atoms of the organic group does not include the number of carbon atoms of the alkoxysilyl group. Examples of the halogen atom include a chlorine atom, a fluorine atom, a bromine atom, and an iodine atom. Examples of the alkoxysilyl group include a trialkoxysilyl group, a dialkoxysilyl group, and a monoalkoxysilyl group. Specific examples thereof include a trimethoxysilyl group, a triethoxysilyl group, a dimethoxysilyl group, and a methoxysilyl group. In the general formula (3), a compound in which R₄ is a hydrogen atom is more preferable from the viewpoints of copper adhesion and copper voids, and copper migration.

Specific examples of the tetrazole derivative (B) represented by the general formulas (1) and (2) include, but are not limited to, 1H-tetrazole-5-carboxylic acid, α,α-difluoro-2H-tetrazole-5-acetic acid, α-hydroxy-2H-tetrazole-5-acetic acid, α-amino-2H-tetrazole-5-acetic acid, methyl 1H-tetrazole-5-carboxylate, ethyl 1H-tetrazole-5-carboxylate, 1H-tetrazole-5-acetic acid, methyl 1H-tetrazole-5-acetate, ethyl 1H-tetrazole-5-acetate, and propyl 1H-tetrazole-5-acetate. Of these, from the viewpoints of copper adhesion and copper migration, 1H-tetrazole-5-carboxylic acid, 1H-tetrazole-5-ethyl carboxylate, 1H-tetrazole-5-acetic acid, and 1H-tetrazole-5-ethyl acetate are preferable, and 1H-tetrazole-5-acetic acid is more preferable. When these compounds are added to the resin composition, they may be in the form of a hydrate.

In one embodiment, the tetrazole derivative (B) has a topological polar surface area (tPSA) of 81 to 200. The topological polar surface area (tPSA) is the area of the polar portion of a molecule's surface, and is an index used primarily in medicinal chemistry to evaluate the cell membrane permeability of drugs. By containing a tetrazole derivative having a tPSA of 81 or more and 200 or less in the photosensitive resin composition, copper adhesion and copper migration suppression effect can be obtained. The reason for this is unclear and, although not limited to theory, it is considered that when the tetrazole derivative has an appropriate polarity of 81 or more and 200 or less, as mentioned in the section on pKa, the interaction with the resin when coordinated to copper is appropriate, and therefore, both copper adhesion and copper migration inhibition can be achieved. Furthermore, when tPSA is 200 or less, the molecular weight becomes small, and therefore the dispersibility of the tetrazole derivative in the photosensitive resin composition becomes satisfactory, and it is considered that the copper adhesion and copper migration suppression effect are exerted.

tPSA was calculated using software called “RDKit”. “RDKit” is an open source Python library used in the field of chemoinformatics. For details about “RDKit”, see, for example, G. Landrum, RDKit: Open-Source Cheminformatics (http://www.rdkit.org.)” The following program was used in the calculation of tPSA in the present disclosure.

### Python 3.8.8

### RDkit 2023.03.3

Examples of the tetrazole derivatives (B) having a tPSA of 81 or more and 200 or less include, but are not limited to, 1H-tetrazole-5-carboxylic acid, 1H-tetrazole-5-acetic acid, 1H-tetrazole-5-propionic acid, 2-[4-(1H-1,2,3,4-tetrazol-5-yl)phenyl]acetic acid, 2-(2H-tetrazol-5-yl)butanedioic acid, 2,2-bis(2-2H-tetrazol-5-yl)ethyl)propanedioic acid, 4-(1H-tetrazol-5-yl)benzoic acid, and 1H-tetrazole-5-butanoic acid. Of these, from the viewpoints of copper adhesion and copper migration, 1H-tetrazole-5-carboxylic acid, 1H-tetrazole-5-acetic acid, and 4-(1H-tetrazol-5-yl)benzoic acid are preferable, and 1H-tetrazole-5-acetic acid is more preferable. When these compounds are added to the resin composition, they may be in the form of a hydrate.

The amount of the tetrazole derivative (B) mixed is preferably 0.001 part by weight or more and 20 parts by weight or less, more preferably 0.01 part by weight or more and 10 parts by weight or less, and still more preferably 0.01 part by weight or more and 5 parts by weight or less, relative to 100 parts by weight of the polyimide precursor or polyimide resin (A). The mixing amount is preferably 0.01 part by weight or more in order to exert sufficient effect from the viewpoints of copper adhesion and copper migration inhibition, and is preferably 10 parts by weight or less, and more preferably 5 parts by weight or less, from the viewpoints of copper adhesion, copper migration inhibition, and solubility in the composition. By setting the amount at 10 parts by weight or less, the reason is unclear and, although not limited to theory, it is assumed that a weak layer is less likely to occur between the copper layer and the resin layer, so that copper adhesion is improved and the ionic components in the resin layer do not increase more than necessary, resulting in satisfactory copper migration.

### (C) Photopolymerization Initiator

The photopolymerization initiator will be described. The photopolymerization initiator is preferably a photoradical polymerization initiator, and preferred examples thereof include, but are not limited to, benzophenone derivatives such as benzophenone, methyl o-benzoylbenzoate, 4-benzoyl-4′-methyl diphenyl ketone, dibenzyl ketone and fluorenone; acetophenone derivatives such as 2,2′-diethoxyacetophenone, 2-hydroxy-2-methylpropiophenone, and 1-hydroxycyclohexyl phenyl ketone; thioxanthone derivatives such as thioxanthone, 2-methylthioxanthone, 2-isopropylthioxanthone, and diethylthioxanthone; benzyl derivatives such as benzyl, benzyl dimethyl ketal, and benzyl-p-methoxyethyl acetal; benzoin derivatives such as benzoin and benzoin methyl ether; oximes such as 1-phenyl-1,2-butanedione-2-(o-methoxycarbonyl)oxime, 1-phenyl-1,2-propanedione-2-(o-methoxycarbonyl)oxime, 1-phenyl-1,2-propanedione-2-(o-ethoxycarbonyl)oxime, 1-phenyl-1,2-propanedione-2-(o-benzoyl)oxime, 1,3-diphenylpropanetrione-2-(o-ethoxycarbonyl)oxime, and 1-phenyl-3-ethoxypropanetrione-2-(o-benzoyl)oxime; N-arylglycines such as N-phenylglycine; peroxides such as benzoyl perchloride; aromatic biimidazole derivatives; titanocene derivatives; and photoacid generators such as α-(n-octanesulfonyloxyimino)-4-methoxybenzyl cyanide. Of the above photopolymerization initiators, oximes are more preferable, particularly in terms of the photosensitivity.

The mixing amount of the photopolymerization initiator (C) is preferably 0.1 part by weight or more and 20 parts by weight, more preferably 1 part by weight or more and 8 parts by weight or less, and still more preferably 1 part by weight or more and 5 parts by weight or less, relative to 100 parts by weight of the polyimide precursor or polyimide resin (A). The mixing amount is preferably 0.1 part by weight or more from the viewpoint of the photosensitivity or patterning ability, and 20 parts by weight or less from the viewpoint of the physical properties of the photosensitive resin layer after curing of the photosensitive resin composition.

### (D) Solvent

The solvent (D) will be described. Examples of the solvent include amides, sulfoxides, ureas, ketones, esters, lactones, ethers, halogenated hydrocarbons, hydrocarbons, alcohols and the like, and it is possible to use N-methyl-2-pyrrolidone, N,N-dimethylacetamide, N,N-dimethylformamide, dimethyl sulfoxide, tetramethylurea, acetone, methyl ethyl ketone, methyl isobutyl ketone, cyclopentanone, cyclohexanone, methyl acetate, ethyl acetate, butyl acetate, diethyl oxalate, ethyl lactate, methyl lactate, butyl lactate, γ-butyrolactone, propylene glycol monomethyl ether acetate, propylene glycol monomethyl ether, benzyl alcohol, phenyl glycol, tetrahydrofurfuryl alcohol, ethylene glycol dimethyl ether, diethylene glycol dimethyl ether, tetrahydrofuran, morpholine, dichloromethane, 1,2-dichloroethane, 1,4-dichlorobutane, chlorobenzene, o-dichlorobenzene, anisole, hexane, heptane, benzene, toluene, xylene, mesitylene and the like. Of these, from the viewpoints of the solubility of the resin, stability of the resin composition and adhesion to the substrate, N-methyl-2-pyrrolidone, dimethyl sulfoxide, tetramethylurea, butyl acetate, ethyl lactate, γ-butyrolactone, propylene glycol monomethyl ether acetate, propylene glycol monomethyl ether, diethylene glycol dimethyl ether, benzyl alcohol, phenyl glycol, 3-methoxy-N,N-dimethylpropanamide, 3-butoxy-N,N-dimethylpropanamide, and tetrahydrofurfuryl alcohol are preferable.

Of these solvents, solvents which completely dissolve the polyimide precursor are preferable and, examples thereof include N-methyl-2-pyrrolidone, N,N-dimethylacetamide, N,N-dimethylformamide, dimethylsulfoxide, tetramethylurea, y-butyrolactone, 3-methoxy-N,N-dimethylpropanamide, 3-butoxy-N,N-dimethylpropanamide and the like. In particular, from the viewpoint of in-plane uniformity when the photosensitive resin composition is applied onto a substrate, y-butyrolactone and 3-methoxy-N,N-dimethylpropanamide are preferable.

The solvent may be alone, or two or more thereof may be mixed and used, but from the viewpoint of appropriately adjusting the stability of the resin composition, two or more thereof are preferably used. When two or more solvents are included, from the viewpoint of the in-plane uniformity, 50% by weight or more of the solvent is preferably either y-butyrolactone or 3-methoxy-N,N-dimethylpropanamide, and more preferably y-butyrolactone.

In the photosensitive resin composition, the amount of the solvent used is preferably 100 to 1,000 parts by weight, more preferably 120 to 700 parts by weight, and still more preferably 125 to 500 parts by weight, relative to 100 parts by weight of the polyimide precursor or polyimide resin (A).

### (E) Radical Polymerizable Compound

The photosensitive resin composition may further include (E) a radical polymerizable compound. When the radical polymerizable compound (E) is used, crosslinking of the photosensitive resin composition proceeds and the moisture permeability of the cured film deteriorates, thus obtaining the effect of suppressing copper migration. The photosensitive resin composition preferably includes the radical polymerizable compound in an amount of 5 parts by weight or more and 150 parts by weight or less relative to 100 parts by weight of the polyimide precursor or polyimide resin (A). In order to obtain satisfactory chemical resistance, the photosensitive resin composition preferably includes the radical polymerizable compound in an amount of 5 parts by weight or more, more preferably 10 parts by weight or more, and still more preferably 20 parts by weight or more. If the radical polymerizable compound is excessively included, the copper adhesion may deteriorate. However, it has been found that the photosensitive resin composition of the present disclosure can obtain high copper adhesion even when including a relatively large amount of the radical polymerizable compound, by including the above-mentioned specific tetrazole derivative. The upper limit value, which can be arbitrarily combined with the above lower limit value, is preferably 150 parts by weight or less, more preferably 100 parts by weight or less, and still more preferably 80 parts by weight or less, from the viewpoint of the patterning properties.

The radical polymerizable compound is not particularly limited as long as it is a compound which undergoes a radical polymerization reaction by a photopolymerization initiator and a thermal polymerization initiator, but is preferably a (meth)acrylic compound and is, for example, represented by the following general formula (43):

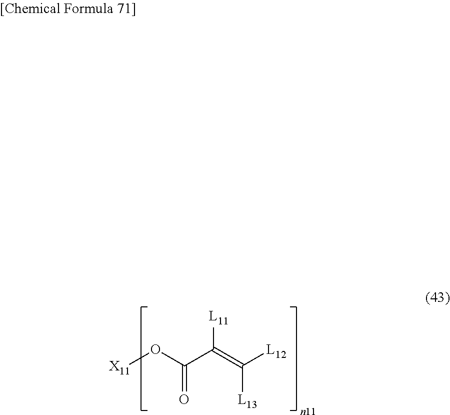

wherein, in formula (43), X₁₁ is an organic group, L₁₁, L₁₂ and L₁₃ are each independently a hydrogen atom, or a monovalent organic group having 1 to 3 carbon atoms, and n₁₁ is an integer of 1 to 10.

Examples of the radical polymerizable compound include, but not limited to, mono- or di-acrylates and methacrylates of ethylene glycol or polyethylene glycol, such as diethylene glycol dimethacrylate and tetraethylene glycol dimethacrylate; mono- or di-acrylates and methacrylates of propylene glycol or polypropylene glycol, mono-, di- or tri-acrylates and methacrylates of glycerol, cyclohexane diacrylate and dimethacrylate, diacrylates and dimethacrylates of 1,4-butanediol, diacrylates and dimethacrylates of 1,6-hexanediol, diacrylates and dimethacrylates of neopentyl glycol, mono- or diacrylates and methacrylates of bisphenol A, benzene trimethacrylates, isobornyl acrylates and methacrylates, acrylamides and derivatives thereof, methacrylamides and derivatives thereof, trimethylolpropane triacrylates and methacrylates, di- or triacrylates and methacrylates of glycerol, di-, tri-, or tetraacrylates and methacrylates of pentaerythritol, and ethylene oxides or propylene oxide adducts of these compounds. More specifically, examples thereof include, but are not limited to, compounds represented by the following formulas (44) and (45):

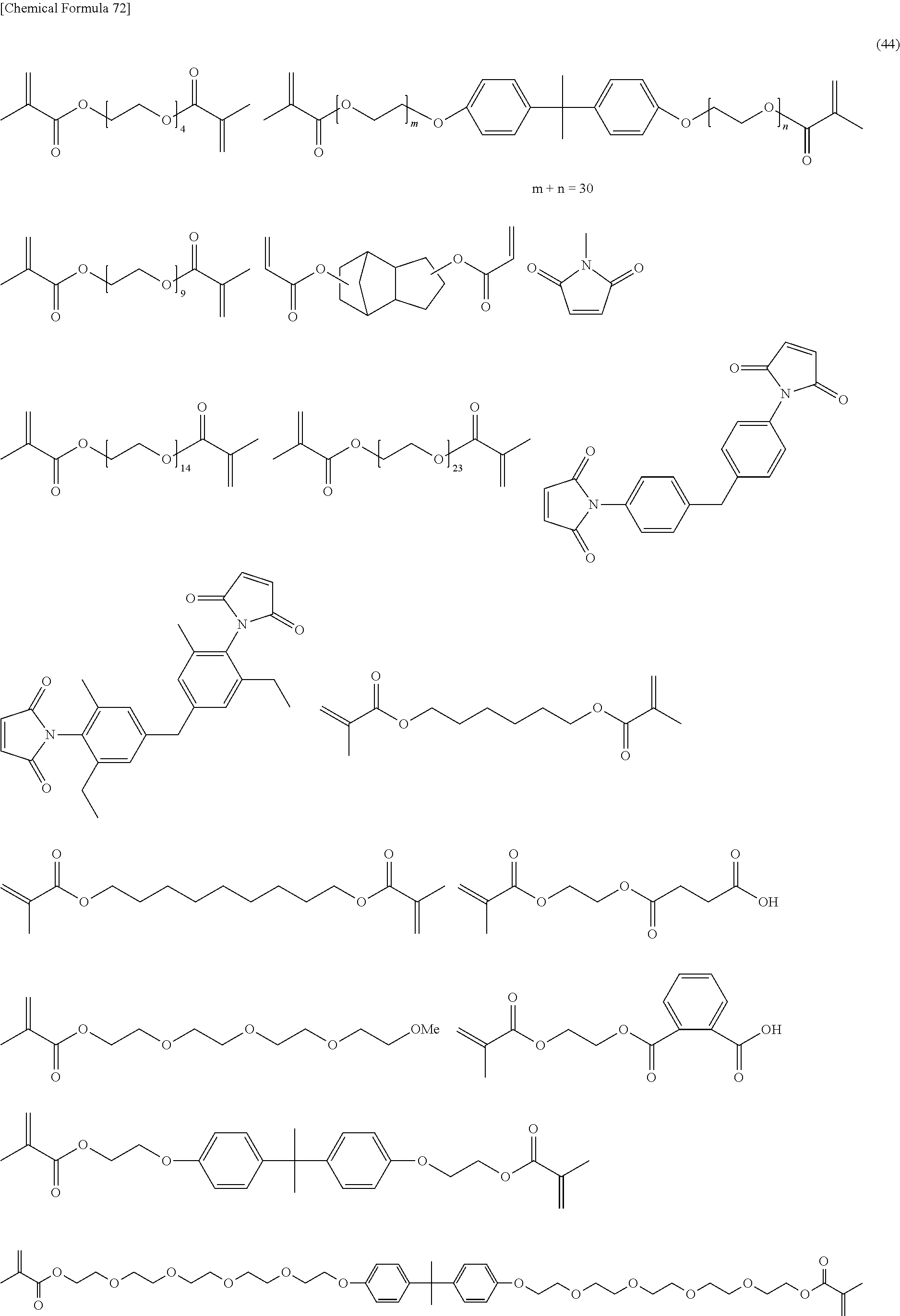

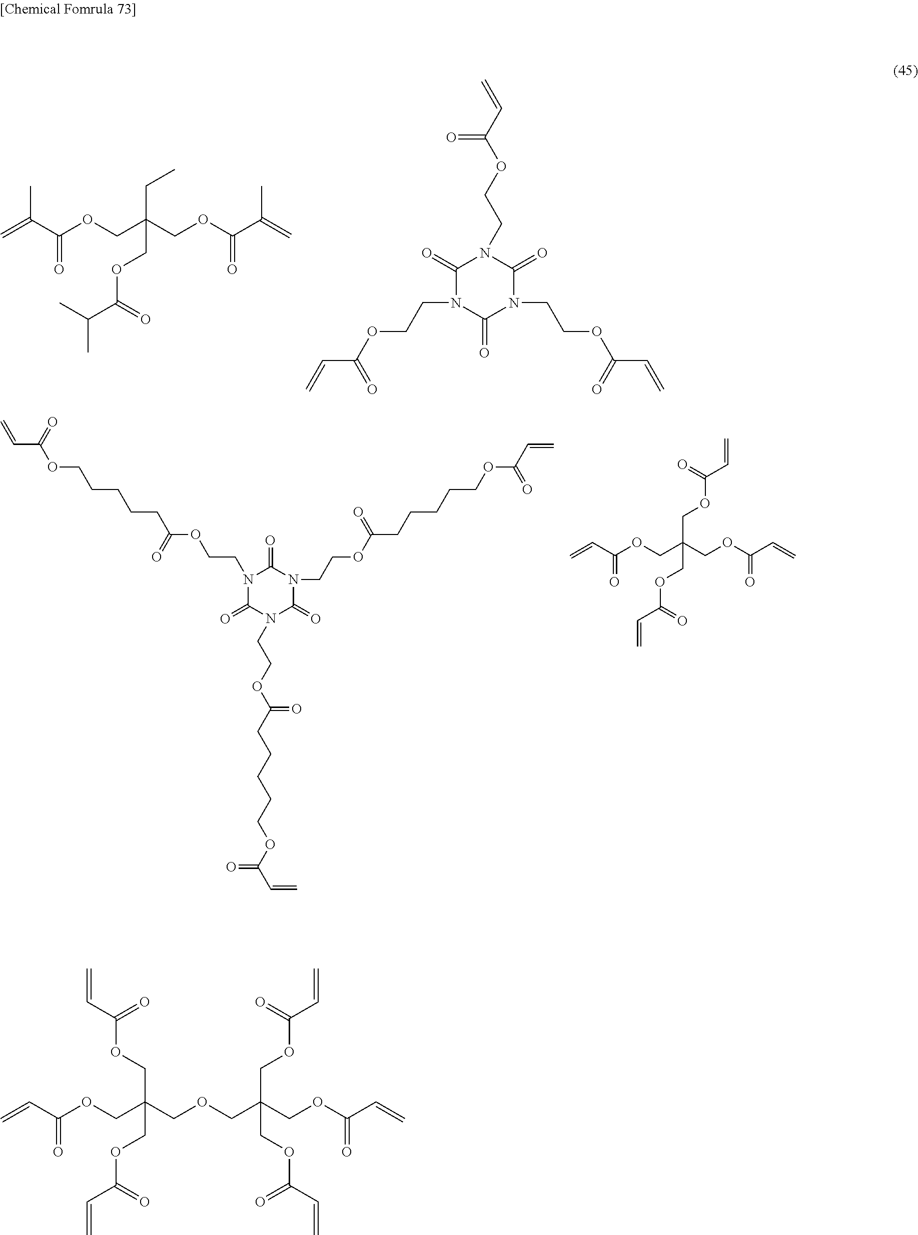

In the present disclosure, when the radical polymerizable compound has one radical polymerizable group, it is referred to as monofunctional, and when the radical polymerizable compound has two or more radical polymerizable groups, it is referred to as x-functional group according to the number x of radical polymerizable groups, but bifunctional or higher functional groups may be collectively referred to as polyfunctional. The radical polymerizable compound may be monofunctional, or bifunctional or higher functional. From the viewpoint of the chemical resistance, the radical polymerizable compound is preferably trifunctional or higher functional, more preferably tetrafunctional or higher functional, and still more preferably hexafunctional or higher functional. On the other hand, from the viewpoint of the elongation at break, it is preferably decafunctional or lower functional.

The molecular weight of the radical polymerizable compound is preferably 100 or more, more preferably 200 or more, and still more preferably 300 or more. The upper limit is preferably 1,000 or less, and more preferably 800 or less. By setting the molecular weight within the above range, the chemical resistance and patterning characteristics are improved.

At least one of the radical polymerizable compounds is preferably a radical polymerizable compound having at least one group of a hydroxyl group and a urea group.

Examples of the radical polymerizable compound having a hydroxyl group in the molecule include a structure represented by the following general formula (46):

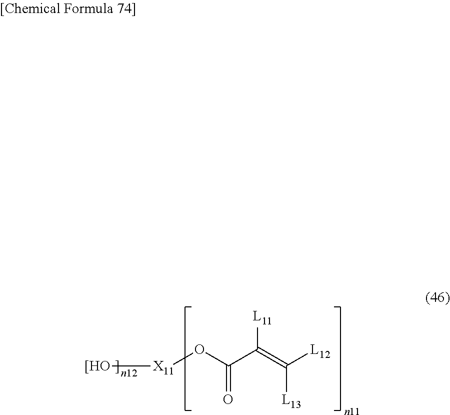

wherein, in formula (46), X₁₁ is an organic group, L₁₁, L₁₂ and L₁₃ are each independently a hydrogen atom, or a monovalent organic group having 1 to 3 carbon atoms, n₁₁ is an integer of 1 to 10, and n₁₂ is an integer of 1 to 10. In the above formula (46), it is preferable that L₁₁ is a hydrogen atom, or a methyl group, and L₁₂ and L₁₃ are a hydrogen atom, from the viewpoint of the radical reactivity. More specifically, examples thereof include, but are not limited to, compounds represented by the following formula (47):

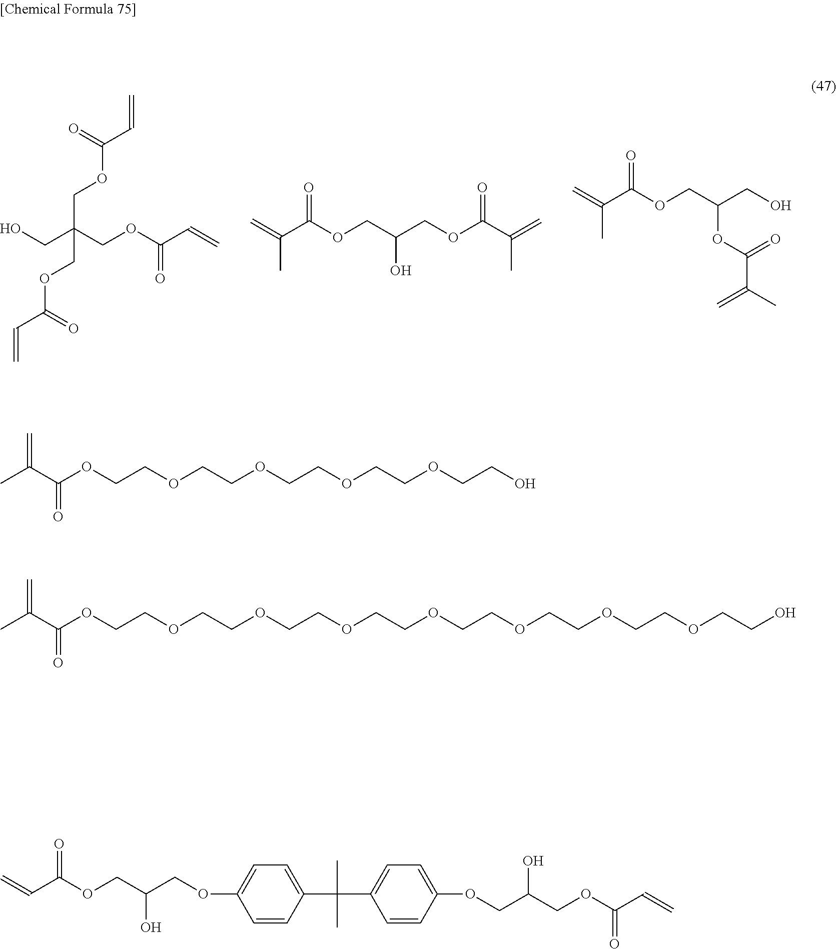

The chemical resistance is particularly improved by having a hydroxyl group in the molecular structure. The number of hydroxyl groups in the molecular structure is preferably 1 or more, and more preferably 2 or more. The upper limit is preferably 10 or less, more preferably 6 or less, and still more preferably 3 or less. By setting the number of hydroxyl groups within the above range, the chemical resistance and adhesion to the substrate are improved.

The radical polymerizable compound having a urea group in the molecule can be represented by the following general formula (48):

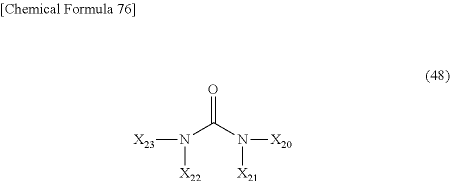

wherein, in formula (48), X₂₀, X₂₁, X₂₂ and X₂₃ are each independently a hydrogen atom, a monovalent organic group having a group represented by the following general formula (49), or a monovalent organic group having 1 to 20 carbon atoms which may contain a heteroatom, and at least one of X₂₀, X₂₁, X₂₂ and X₂₃ is a monovalent organic group having a group represented by the following general formula (49), and:

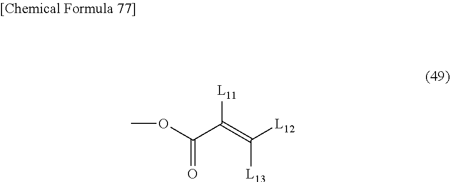

wherein, in formula (49), L₁₁, L₁₂ and L₁₃ are each independently a hydrogen atom, or a monovalent organic group having 1 to 3 carbon atoms. In the above formula (49), it is more preferable that L₁₁ is a hydrogen atom, or a methyl group, and L₁₂ and L₁₃ are a hydrogen atom, from the viewpoint of the radical reactivity.

Examples of the heteroatom include an oxygen atom, a nitrogen atom, a phosphorus atom, and a sulfur atom.

In the formula (48), when X₂₀, X₂₁, X₂₂ and X₂₃ are a monovalent organic group having 1 to 20 carbon atoms which may contain a heteroatom, it is more preferable that they contain an oxygen atom from the viewpoint of the developability. The number of carbon atoms is not limited as long as it is 1 to 20, but from the viewpoint of the heat resistance, the number of carbon atoms is preferably 1 to 10, and more preferably 3 to 10. X₂₀, X₂₁, X₂₂ and X₂₃ in formula (48) may be bonded to each other to form a cyclic structure, but from the viewpoint of the chemical resistance, it is preferable that they do not have a cyclic structure. When X₂₀, X₂₁, X₂₂, X₂₃ are bonded to each other to form a cyclic structure, the degree of freedom of the bond angle of the urea group is lost, thus making it difficult to form a strong hydrogen bond. From the viewpoint of forming a hydrogen bond with other molecules, it is preferable that at least one of X₂₀, X₂₁, X₂₂ and X₂₃ is a hydrogen atom. On the other hand, from the viewpoint of the solubility, it is preferable that X₂₀, X₂₁, X₂₂ and X₂₃ each have two or less hydrogen atoms. Specifically, examples thereof include compounds represented by the following formula:

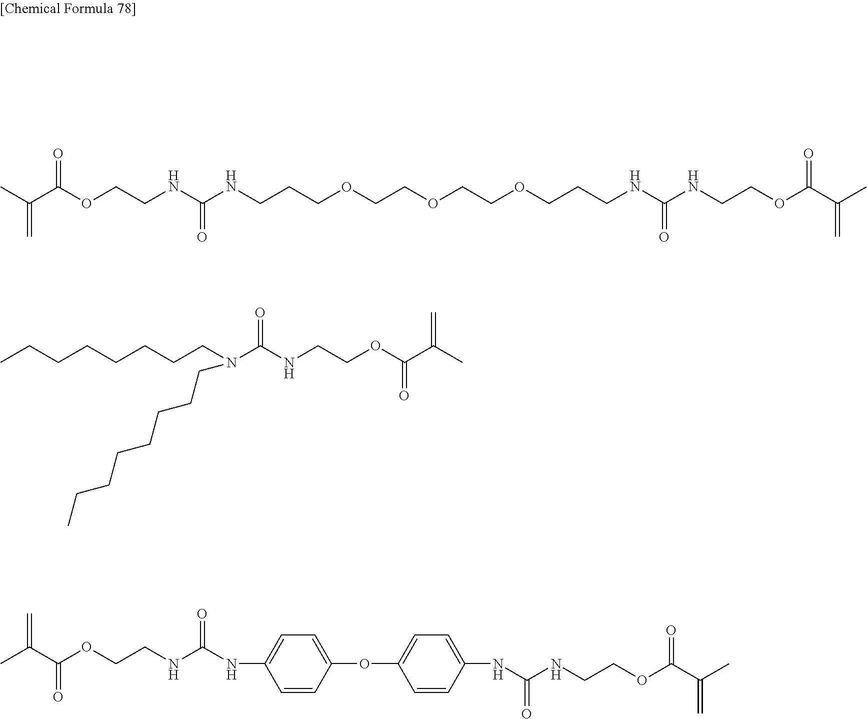

The radical polymerizable compound preferably has at least one hydroxyl group and at least one urea group in the molecule. The radical polymerizable compound having at least one hydroxyl group and at least one urea group in the molecule can be represented by, for example, the following general formula (50):

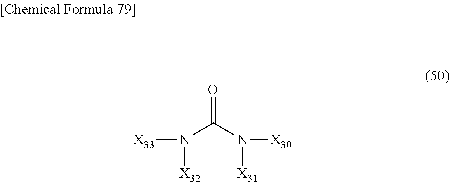

wherein, in formula (50), X₃₀, X₃₁, X₃₂ and X₃₃ are each independently a hydrogen atom, a monovalent organic group having a group the following general formula (51), or a monovalent organic group having 1 to 20 carbon atoms which may contain a heteroatom, at least one of X₃₀, X₃₁, X₃₂ and X₃₃ is a monovalent organic group having a group represented by the following general formula (51), and at least one of them is a hydroxyl group, and:

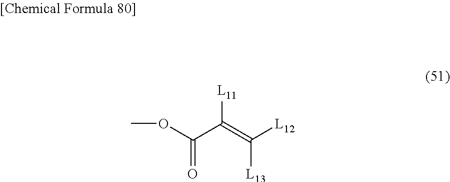

wherein, in formula (51), L₁₁, L₁₂ and L₁₃ are each independently a hydrogen atom, or a monovalent organic group having 1 to 3 carbon atoms. In the above formula (51), it is more preferable that L₁₁ is a hydrogen atom, or a methyl group, and L₁₂ and L₁₃ are a hydrogen atom, from the viewpoint of the radical reactivity.

In formula (50), when X₃₀, X₃₁, X₃₂, X₃₃ are a monovalent organic group having 1 to 20 carbon atoms which may contain a heteroatom, it is more preferable that they contain an oxygen atom from the viewpoint of the developability. The number of carbon atoms is not limited as long as it is 1 to 20, but from the viewpoint of the heat resistance, the number of carbon atoms is preferably 1 to 10, and more preferably 3 to 10. In formula (51), X₃₀, X₃₁, X₃₂ and X₃₃ may be bonded to each other to form a cyclic structure, but from the viewpoint of the chemical resistance, it is preferable that they do not have a cyclic structure. When X₃₀, X₃₁, X₃₂ and X₃₃ are bonded to each other to form a cyclic structure, the degree of freedom of the bond angle of the urea group is lost, making it difficult to form strong hydrogen bonds. From the viewpoint of forming a hydrogen bond with other molecules, it is preferable that at least one of X₃₀, X₃₁, X₃₂ and X₃₃ is a hydrogen atom. On the other hand, from the viewpoint of the solubility, it is preferable that X₃₀, X₃₁, X₃₂ and X₃₃ each have two or less hydrogen atoms. Specifically, examples thereof include compounds represented by the following formula:

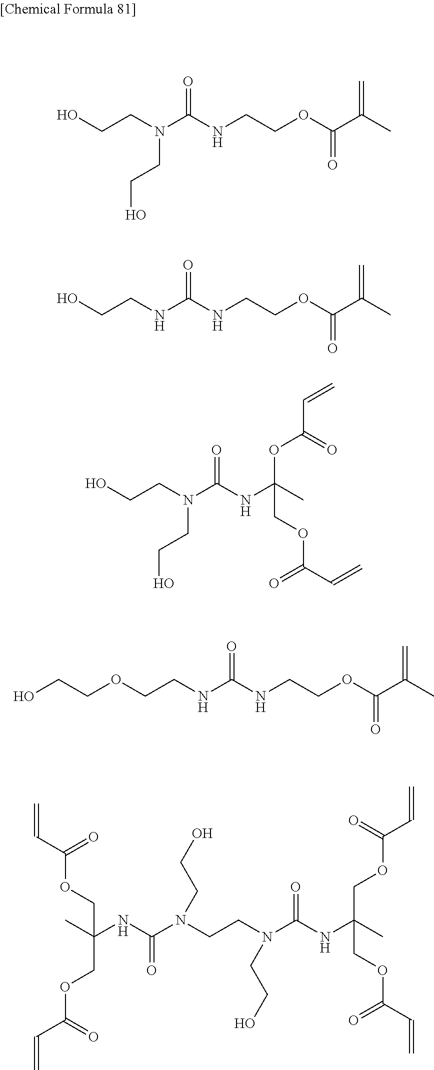

Of the radical polymerizable compounds, the method for producing a radical polymerizable compound having a urea group is not particularly limited, but it can be obtained, for example, by reacting an isocyanate compound having a radical polymerizable group with an amine-containing compound. When the amine-containing compound has a functional group, such as a hydroxyl group capable of reacting with an isocyanate, a part of the isocyanate compound may contain a compound reacted with the functional group such as a hydroxyl group.

The radical polymerizable compound may be used alone, but it is preferable to use two or more thereof in combination. By using a mixture of two or more thereof, the chemical resistance and in-plane uniformity are improved. The reason why the in-plane uniformity is improved is merely speculative; however, it is considered that when a large amount of only one type of radical polymerizable compound is added, microphase separation occurs between the compound and the polyimide precursor component in the varnish. For the above reasons, when the radical polymerizable compound is used alone, the amount thereof is preferably 60 parts by weight or less, and more preferably 40 parts by weight or less, relative to 100 parts by weight of the polyimide precursor.

When two or more types of radical polymerizable compounds are used in combination, the number of types is preferably 6 or less, and more preferably 4 or less, from the viewpoint of controlling the crosslink density.

When a plurality of radical polymerizable compounds are used in combination, it is preferable that at least one of the plurality of radical polymerizable compounds has a different number of functional groups. When three or more radical polymerizable compounds are used, it is sufficient that at least one of them has a different number of functional groups, but it is preferable that all the radical polymerizable compounds have different numbers of functional groups. When a plurality of radical polymerizable compounds are used, it is preferable to include at least one monofunctional radical polymerizable compound from the viewpoint of the elongation at break.

When two or more types of radical polymerizable compounds are used in combination, it is preferable to include at least one nitrogen atom-containing radical polymerizable compound and at least one nitrogen atom-free radical polymerizable compound. The nitrogen atom-containing radical polymerizable compound is preferably a urea group-containing radical polymerizable compound. The nitrogen-containing radical polymerizable compound has excellent chemical resistance because it is capable of forming strong hydrogen bond. However, when a plurality of nitrogen-containing radical polymerizable compounds are added, a complex hydrogen bond network is formed, resulting in insufficient solubility.

The photosensitive resin composition may further include components other than the above components (A) to (E). Examples of the components other than the components (A) to (E) include, but are not limited to, a thermal crosslinking agent (F), a heterocyclic compound (G), a thermal base generator (H), a hindered phenol compound (I), an organic titanium compound (J), an adhesion aid (K), a sensitizer (L), and a polymerization inhibitor (M).

### (F) Thermal Crosslinking Agent

In order to suppress the copper adhesion of the polyimide film and copper migration, the photosensitive resin composition may optionally include a thermal crosslinking agent.

The thermal crosslinking agent means a compound which undergoes an addition reaction or a condensation polymerization reaction by heat. These reactions occur by combinations of the polyimide resin (A) and the thermal crosslinking agent (F), the thermal crosslinking agents (F), and the thermal crosslinking agent (F) and other components mentioned later, and the reaction temperature is preferably 150° C. or higher.

Examples of the thermal crosslinking agent include an alkoxymethyl compound, an epoxy compound, an oxetane compound, a bismaleimide compound, an allyl compound, and a blocked isocyanate compound. From the viewpoint of suppressing cure shrinkage, the thermal crosslinking agent (F) preferably contains a nitrogen atom.

Examples of the alkoxymethyl compound include, but are not limited to, compounds of the following formulas:

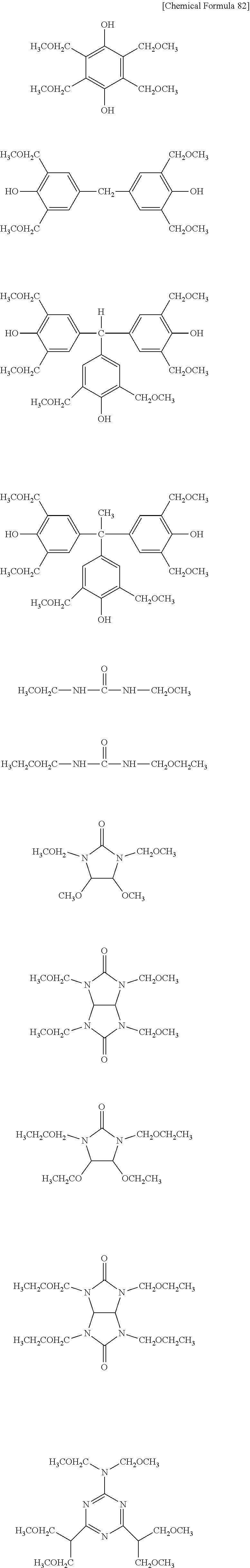

Examples of commercially available alkoxymethyl compounds include alkylated urea resin (product name: NIKALAC MX290) and 1,3,4,6-tetrakis(methoxymethyl)glycoluril (product name: NIKALAC MX270).

Examples of the epoxy compound include 4-hydroxybutyl acrylate glycidyl ether, epoxy compounds having a bisphenol A type group, and hydrogenated bisphenol A diglycidyl ether. For example, EPOLITE 4000 (product name, manufactured by Kyoeisha Chemical Co., Ltd.) can be suitably used.

Examples of the oxetane compound include 1,4-bis{[(3-ethyl-3-oxetanyl)methoxy]methyl})benzene, bis[l-ethyl(3-oxetanyl)]methyl ether, 4,4′-bis[(3-ethyl-3-oxetanyl)methyl]biphenyl, 4,4′-bis(3-ethyl-3-oxetanylmethoxy)biphenyl, ethylene glycol bis(3-ethyl-3-oxetanylmethyl)ether, diethylene glycol bis(3-ethyl-3-oxetanylmethyl)ether, bis(3-ethyl-3-oxetanylmethyl)diphenoate, trimethylolpropane tris(3-ethyl-3-oxetanylmethyl)ether, pentaerythritol tetrakis(3-ethyl-3-oxetanylmethyl)ether, poly[[3-[(3-ethyl-3-oxetanyl)methoxy]propyl]silasesquioxane]derivatives, oxetanyl silicate, phenol novolac-type oxetane, and 1,3-bis[(3-ethyloxetan-3-yl)methoxy]benzene. For example, OXT121 (product name, manufactured by Toagosei Co., Ltd.) and OXT221 (product name, manufactured by Toagosei Co., Ltd.) can be suitably used.

Examples of the bismaleimide compound include 1,2-bis(maleimide)ethane, 1,3-bis(maleimide)propane, 1,4-bis(maleimide)butane, 1,5-bis(maleimide)pentane, 1,6-bis(maleimide)hexane, 2,2,4-trimethyl-1,6-bis(maleimide)hexane, N,N′-1,3-phenylenebis(maleimide), 4-methyl-N,N′-1,3-phenylenebis(maleimide), N,N′-1,4-phenylenebis(maleimide), 3-methyl-N,N′-1,4-phenylenebis(maleimide), 4,4′-bis(maleimide)diphenylmethane, 3,3′-diethyl-5,5′-dimethyl-4,4′-bis(maleimide)diphenylmethane, and 2,2-bis[4-(4-maleimidophenoxy)phenyl]propane.

Examples of the allyl compound include allyl alcohol, allyl anisole, allyl benzoate ester, allyl cinnamate ester, N-allyloxyphthalimide, allylphenol, allyl phenyl sulfone, allyl urea, diallyl phthalate, diallyl isophthalate, diallyl terephthalate, diallyl maleate, diallyl isocyanurate, triallyl amine, triallyl isocyanurate, triallyl cyanurate, triallyl amine, triallyl 1,3,5-benzenetricarboxylate, triallyl trimellitate, triallyl phosphate, triallyl phosphite, and triallyl citrate.

Examples of the blocked isocyanate compound include hexamethylene diisocyanate-based blocked isocyanates (e.g., manufactured by Asahi Kasei Corporation, trade names: DURANATE SBN-70D, SBB-70P, SBF-70E, TPA-B80E, 17B-60P, MF-B60B, E402-B80B, MF-K60B, and WM44-L70G; manufactured by Mitsui Chemicals, Inc., trade name: TAKENATE B-882N; manufactured by Baxenden, trade names: 7960, 7961, 7982, 7991, and 7992, etc.); tolylene diisocyanate-based blocked isocyanates (e.g., manufactured by Mitsui Chemicals, Inc., trade name: TAKENATE B-830, etc.); 4,4′-diphenylmethane diisocyanate-based blocked isocyanates (e.g., trade name: TAKENATE B-815N, manufactured by Mitsui Chemicals, Inc.; trade names: BRONATE PMD-OA01, and PMD-MA01, manufactured by Daiei Sangyo Co., Ltd.), 1,3-bis(isocyanatomethyl)cyclohexane-based blocked isocyanates (e.g., trade name: TAKENATE B-846N, manufactured by Mitsui Chemicals, Inc.; trade names: CORONATE BI-301, 2507, and 2554, manufactured by Tosoh Corporation); and isophorone diisocyanate-based blocked isocyanates (e.g., trade names: 7950, 7951, and 7990, manufactured by Baxenden).

Of these, blocked isocyanate compounds and bismaleimide compounds are preferable from the viewpoint of the storage stability. The thermal crosslinking agent (F) may be used alone or in combination of two or more thereof.

The content of the thermal crosslinking agent (F) in the photosensitive resin composition of the present disclosure is preferably 0.2 part by weight to 40 parts by weight relative to 100 parts by weight of the polyimide precursor or polyimide resin (A). From the viewpoint of the chemical resistance, the lower limit of the content of the thermal crosslinking agent is more preferably 1 part by weight or more, and still more preferably 5 parts by weight or more. From the viewpoint of the storage stability of the photosensitive resin composition of the present disclosure, the upper limit of the content of the thermal crosslinking agent is more preferably 30 parts by weight or less, and still more preferably 20 parts by weight or less.

### (G) Heterocyclic Compound

The photosensitive resin composition of the present disclosure may contain, in addition to the tetrazole derivative (B), a heterocyclic compound for improving the copper adhesion, developability, copper migration inhibition ability and the like. Examples of the heterocyclic compound include imidazole derivatives, triazole derivatives, tetrazole derivatives other than (B), and purine derivatives.

Specific examples of purine derivatives include purine, adenine, guanine, hypoxanthine, xanthine, theobromine, caffeine, uric acid, isoguanine, 2,6-diaminopurine, 9-methyladenine, 2-hydroxyadenine, 2-methyladenine, 1-methyladenine, N-methyladenine, N,N-dimethyladenine, 2-fluoroadenine, 9-(2-hydroxyethyl)adenine, guanine oxime, N-(2-hydroxyethyl)adenine, 8-aminopurine, 6-amino-8-phenyl-9H-purine, 1-ethyladenine, 6-ethylaminopurine, 1-benzyladenine, N-methylguanine, 7-(2-hydroxyethyl)guanine, N-(3-chlorophenyl)guanine, N-(3-ethylphenyl)guanine, 2-azaadenine, 5-azaadenine, 8-azaadenine, 8-azaguanine, 8-azapurine, 8-azaxanthine, 8-azahypoxanthine, and derivatives thereof. These heterocyclic compounds may be used alone or in combination of two or more thereof.

When the photosensitive resin composition includes a heterocyclic compound, the amount of the heterocyclic compound is preferably 0.1 to 10 parts by weight, and more preferably 0.5 to 5 parts by weight, relative to 100 parts by weight of the polyimide precursor or polyimide resin (A), from the viewpoint of the copper adhesion. When the mixing amount is 0.1 part by weight or more, discoloration of the copper is suppressed when the photosensitive resin composition is formed on copper, while when the mixing amount is 10 parts by weight or less, excellent copper adhesion is achieved.

### (H) Thermal Base Generator

The photosensitive resin composition may include a thermal base generator. The base generator refers to a compound which generates a base when heated. By including the thermal base generator, imidization of the photosensitive resin composition can be further promoted.

The thermal base generator is not particularly limited on type, but examples thereof include an amine compound protected with a tert-butoxycarbonyl group, or a thermal base generator disclosed in WO 2017/038598. However, the present invention is not limited to these, and other known thermal base generators can also be used.

Examples of the amine compound protected with a tert-butoxycarbonyl group include, but are not limited to, ethanolamine, 3-amino-1-propanol, 1-amino-2-propanol, 2-amino-1-propanol, 4-amino-1-butanol, 2-amino-1-butanol, 1-amino-2-butanol, 3-amino-2,2-dimethyl-1-propanol, 4-amino-2-methyl-1-butanol, valinol, 3-amino-1,2-propanediol, 2-amino-1,3-propanediol, tyramine, norephedrine, 2-amino-1-phenyl-1,3-propanediol, 2-aminocyclohexanol, 4-aminocyclohexanol, 4-aminocyclohexaneethanol, 4-(2-aminoethyl)cyclohexanol, N-methylethanolamine, 3-(methylamino)-1-propanol, 3-(isopropylamino)propanol, N-cyclohexylethanolamine, α-[2-(methylamino)ethyl]benzyl alcohol, diethanolamine, diisopropanolamine, 3-pyrrolidinol, 2-pyrrolidinemethanol, 4-hydroxypiperidine, 3-hydroxypiperidine, 4-hydroxy-4-phenylpiperidine, 4-(3-hydroxyphenyl)piperidine, 4-piperidinemethanol, 3-piperidinemethanol, 2-piperidinemethanol, 4-piperidineethanol, 2-piperidineethanol, 2-(4-piperidyl)-2-propanol, 1,4-butanolbis(3-aminopropyl)ether, 1,2-bis(2-aminoethoxy)ethane, 2,2′-oxybis(ethylamine), 1,14-diamino-3,6,9,12-tetraoxatetradecane, 1-aza-15-crown-5-ether, diethylene glycol bis(3-aminopropyl)ether, 1,11-diamino-3,6,9-trioxaundecane, and compounds in which the amino group of an amino acid or a derivative thereof is protected with a tert-butoxycarbonyl group.

The mixing amount of the thermal base generator is preferably 0.1 part by weight or more and 30 parts by weight or less, and more preferably 1 part by weight or more and 20 parts by weight or less, relative to 100 parts by weight of the polyimide precursor or polyimide resin (A). The mixing amount is preferably 0.1 part by weight or more from the viewpoint of the imidization-accelerating effect, and is preferably 20 parts by weight or less from the viewpoint of the physical properties of the photosensitive resin layer after curing of the photosensitive resin composition.

### (I) Hindered Phenol Compound

In order to suppress discoloration on the copper surface, the photosensitive resin composition may optionally include a hindered phenol compound. Examples of the hindered phenolic compound include, but are not limited to, 2,6-di-t-butyl-4-methylphenol, 2,5-di-t-butyl-hydroquinone, octadecyl-3-(3,5-di-t-butyl-4-hydroxyphenyl)propionate, isooctyl-3-(3,5-di-t-butyl-4-hydroxyphenyl)propionate, 4,4′-methylenebis(2,6-di-t-butylphenol), 4,4′-thio-bis(3-methyl-6-t-butylphenol), 4,4′-butylidene-bis(3-methyl-6-t-butylphenol), triethylene glycol-bis[3-(3-t-butyl-5-methyl-4-hydroxyphenyl)propionate], 1,6-hexanediol-bis[3-(3,5-di-t-butyl-4-hydroxyphenyl)propionate], 2,2-thio-diethylenebis[3-(3,5-di-t-butyl-4-hydroxyphenyl)propionate], N,N′-hexamethylenebis(3,5-di-t-butyl-4-hydroxy-hydrocinnamide), 2,2′-methylene-bis(4-methyl-6-t-butylphenol), 2,2′-methylene-bis(4-ethyl-6-t-butylphenol), 15 pentaerythrityl-tetrakis[3-(3,5-di-t-butyl-4-hydroxyphenyl)propionate], tris-(3,5-di-t-butyl-4-hydroxybenzyl)-isocyanurate, 1,3,5-trimethyl-2,4,6-tris(3,5-di-t-butyl-4-hydroxybenzyl)benzene and the like.

Examples of the hindered phenolic compound also include, but are not limited to, 1,3,5-tris(3-hydroxy-2,6-dimethyl-4-isopropylbenzyl)-1,3,5-triazine-2,4,6-(1H,3H,5H)-trione, 1,3,5-tris(4-t-butyl-3-hydroxy-2,6-dimethylbenzyl)-1,3,5-triazine-2,4,6-(1H,3H,5H)-trione, 1,3,5-tris(4-s-butyl-3-hydroxy-2,6-dimethylbenzyl)-1,3,5-triazine-2,4,6-(1H,3H,5H)-trione, 1,3,5-tris[4-(1-ethylpropyl)-3-hydroxy-2,6-dimethylbenzyl]-1,3,5-triazine-2,4,6-(1H,3H,5H)-trione, 1,3,5-tris[4-triethylmethyl-3-hydroxy-2,6-dimethylbenzyl]-1,3,5-triazine-2,4,6-(1H,3H,5H)-trione, 1,3,5-tris(3-hydroxy-2,6-dimethyl-4-phenylbenzyl)-1,3,5-triazine-2,4,6-(1H,3H,5H)-trione, 1,3,5-tris(4-t-butyl-3-hydroxy-2,5,6-trimethylbenzyl)-1,3,5-triazine-2,4,6-(1H,3H,5H)-trione, 1,3,5-tris(4-t-butyl-5-ethyl-3-hydroxy-2,6-dimethylbenzyl)-1,3,5-triazine-2,4,6-(1H,3H,5H)-trione, 1,3,5-tris(4-t-butyl-6-ethyl-3-hydroxy-2-methylbenzyl)-1,3,5-triazine-2,4,6-(1H,3H,5H)-trione, 1,3,5-tris(4-t-butyl-6-ethyl-3-hydroxy-2,5-dimethylbenzyl)-1,3,5-triazine-2,4,6-(1H,3H,5H)-trione, 1,3,5-tris(4-t-butyl-5,6-diethyl-3-hydroxy-2-methylbenzyl)-1,3,5-triazine-2,4,6-(1H,3H,5H)-trione, 1,3,5-tris(4-t-butyl-3-hydroxy-2-methylbenzyl)-1,3,5-triazine-2,4,6-(1H,3H,5H)-trione, 1,3,5-tris(4-t-butyl-3-hydroxy-2,5-dimethylbenzyl)-1,3,5-triazine-2,4,6-(1H,3H,5H)-trione, 1,3,5-tris(4-t-butyl-5-ethyl-3-hydroxy-2-methylbenzyl)-1,3,5-triazine-2,4,6-(1H,3H,5H)-trione and the like.

Of these, 1,3,5-tris(4-t-butyl-3-hydroxy-2,6-dimethylbenzyl)-1,3,5-triazine-2,4,6-(1H,3H,5H)-trione is particularly preferable.

The mixing amount of the hindered phenol compound mixed is preferably 0.1 to 20 parts by weight, and more preferably 0.5 to 10 parts by weight, relative to 100 parts by weight of the polyimide precursor (A), from the viewpoint of the photosensitivity. When the mixing amount is 0.1 part by weight or more, for example, when the photosensitive resin composition is formed on copper or a copper alloy, discoloration and corrosion of the copper or the copper alloy are prevented, while when the mixing amount is 20 parts by weight or less, the photosensitivity is excellent.

### (J) Organic Titanium Compound

The photosensitive resin composition may include an organic titanium compound. When the organic titanium compound is included, it is possible to form a photosensitive resin layer excellent in chemical resistance even when cured at a low temperature.

Examples of the usable organic titanium compound include those in which an organic chemical substance is bonded to a titanium atom via a covalent bond or an ionic bond.

Specific examples of the organic titanium compound are shown in I) to VII) below:

I) Ttanium chelate compounds: Of these, titanium chelates having two or more alkoxy groups are more preferable since the photosensitive resin composition has storage stability and satisfactory pattern can be obtained. Specific examples thereof include titanium bis(triethanolamine) diisopropoxide, titanium di(n-butoxide)bis(2,4-pentanedionate), titanium diisopropoxide bis(2,4-pentanedionate), titanium diisopropoxide bis(tetramethylheptanedionate), titanium diisopropoxide bis(ethylacetate) and the like.

II) Tetraalkoxy titanium compounds: for example, titanium tetra(n-butoxide), titanium tetraethoxide, titanium tetra(2-ethylhexoside), titanium tetraisobutoxide, titanium tetraisopropoxide, titanium tetramethoxide, titanium tetramethoxypropoxide, titanium tetramethylphenoxide, titanium tetra(n-nonyloxide), titanium tetra(n-propoxide), titanium tetrastearyloxide, titanium tetrakis[bis{2,2-(allyloxymethyl)butoxide)}] and the like.

III) Ttanocene compounds: for example, pentamethylcyclopentadienyl titanium trimethoxide, bis(η5-2,4-cyclopentadien-1-yl)bis(2,6-difluorophenyl)titanium, bis(η5-2,4-cyclopentadien-1-yl)bis(2,6-difluoro-3-(1H-pyrrol-1-yl)phenyl)titanium and the like.

IV) Monoalkoxytitanium compounds: for example, titanium tris(dioctylphosphate) isopropoxide, titanium tris(dodecylbenzenesulfonate) isopropoxide and the like.

V) Titanium oxide compounds: for example, titanium oxide bis(pentanedionate), titanium oxide bis(tetramniethylheptanedionate), phthalocyanine titanium oxide and the like.

VI) Ttanium tetraacetylacetonate compounds: for example, titanium tetraacetylacetonate and the like.

VII) Titanate coupling agents: for example, isopropyltridodecylbenzenesulfonyl titanate and the like.

Of these, the organic titanium compound is preferably at least one compound selected from the group consisting of I) titanium chelate compounds, II) tetraalkoxy titanium compounds and III) titanocene compounds mentioned above, from the viewpoint of exhibiting more satisfactory chemical resistance. In particular, titanium diisopropoxide bis(ethylacetoacetate), titanium tetra(n-butoxide) and bis(η5-2,4-cyclopentadien-1-yl)bis(2,6-difluoro-3-(1H-pyrrol-1-yl)phenyl)titanium are preferable.

When the organic titanium compound is mixed, the mixing amount thereof is preferably 0.05 to 10 parts by weight, and more preferably 0.1 to 2 parts by weight, relative to 100 parts by weight of the polyimide precursor (A). When the mixing amount thereof is 0.05 part by weight or more, satisfactory heat resistance and chemical resistance are exhibited, while when it is 10 parts by weight or less, excellent storage stability is achieved.

### (K) Adhesion Aid

The photosensitive resin composition may optionally include an adhesion aid in order to improve the adhesion between the film formed by using the photosensitive resin composition and a substrate. Examples of the adhesion aid include silane coupling agents such as γ-aminopropyldimethoxysilane, N-(β-aminoethyl)-γ-aminopropylmethyldimethoxysilane, γ-glycidoxypropylmethyldimethoxysilane, γ-mercaptopropylmethyldimethoxysilane, 3-methacryloxypropyldimethoxymethylsilane, 3-methacryloxypropyltrimethoxysilane, dimethoxymethyl-3-piperidinopropylsilane, diethoxy-3-glycidoxypropylmethylsilane, N-(3-diethoxymethylsilylpropyl)succinimide, N-[3-(triethoxysilyl)propyl]phthalamic acid, benzophenone-3,3′-bis(N-[3-triethoxysilyl]propylamide)-4,4′-dicarboxylic acid, benzene-1,4-bis(N-[3-triethoxysilyl]propylamide)-2,5-dicarboxylic acid, 3-(triethoxysilyl)propylsuccinic anhydride, N-phenylaminopropyltrimethoxysilane, 3-ureidopropyltrimethoxysilane, 3-ureidopropyltriethoxysilane, and 3-(trialkoxysilyl)propylsuccinic anhydride; and aluminum-based adhesion aids such as aluminum tris(ethylacetoacetate), aluminum tris(acetylacetonate), and ethylacetoacetate aluminum diisopropylate.

Of these adhesion aids, it is more preferable to use silane coupling agents in terms of the adhesive strength. When the photosensitive resin composition includes an adhesion aid, the mixing amount of the adhesion aid is preferably within a range of 0.5 to 25 parts by weight relative to 100 parts by weight of the polyimide precursor (A).

Examples of silane coupling agents include, but are not limited to, 3-mercaptopropyltrimethoxysilane (manufactured by Shin-Etsu Chemical Co., Ltd.: trade name of KBM803, manufactured by CHISSO CORPORATION: trade name of Sila-Ace S810), N-phenyl-3-aminopropyltrimethoxysilane (manufactured by Shin-Etsu Chemical Co., Ltd.: trade name of KBM573), 3-mercaptopropyltriethoxysilane (manufactured by Azmax Corporation: trade name of SIM6475.0), 3-mercaptopropylmethyldimethoxysilane (manufactured by Shin-Etsu Chemical Co., Ltd.: trade name of LS1375, manufactured by Azmax Corporation: trade name of SIM6474.0), mercaptomethyltrimethoxysilane (manufactured by Azmax Corporation: trade name of SIM6473.5C), mercaptomethylmethyldimethoxysilane (manufactured by Azmax Corporation: trade name of SIM6473.0), 3-mercaptopropyldiethoxymethoxysilane, 3-mercaptopropylethoxydimethoxysilane, 3-mercaptopropyltripropoxysilane, 3-mercaptopropyldiethoxypropoxysilane, 3-mercaptopropylethoxydipropoxysilane, 3-mercaptopropyldimethoxypropoxysilane, 3-mercaptopropylmethoxydipropoxysilane, 2-mercaptoethyltrimethoxysilane, 2-mercaptoethyldiethoxymethoxysilane, 2-mercaptoethylethoxydimethoxysilane, 2-mercaptoethyltripropoxysilane, 2-mercaptoethyltripropoxysilane, 2-mercaptoethylethoxydipropoxysilane, 2-mercaptoethyldimethoxypropoxysilane, 2-mercaptoethylmethoxydipropoxysilane, 4-mercaptobutyltrimethoxysilane, 4-mercaptobutyltriethoxysilane, 4-mercaptobutyltripropoxysilane, 2-(3,4-epoxycyclohexyl) ethyltrimethoxysilane, (3-triethoxysilylpropyl)-t-butyl carbamate, 4,4-carbonylbis(2-(((3-triethoxysilyl)propyl)amino)carbonyl) benzoic acid, 2-(3-triethoxysilylpropylcarbamoyl) benzoic acid and the like.

Examples of silane coupling agents also include, but are not limited to, N-(3-triethoxysilylpropyl)urea (manufactured by Shin-Etsu Chemical Co., Ltd.: trade name of LS3610, manufactured by Azmax Corporation: trade name of SIU9055.0), N-(3-trimethoxysilylpropyl)urea (manufactured by Azmax Corporation: trade name of SIU9058.0), N-(3-diethoxymethoxysilylpropyl)urea, N-(3-ethoxydimethoxysilylpropyl)urea, N-(3-tripropoxysilylpropyl)urea, N-(3-diethoxypropoxysilylpropyl)urea, N-(3-ethoxydipropoxysilylpropyl)urea, N-(3-dimethoxypropoxysilylpropyl)urea, N-(3-methoxydipropoxysilylpropyl)urea, N-(3-trimethoxysilylethyl)urea, N-(3-ethoxydimethoxysilylethyl)urea, N-(3-tripropoxysilylethyl)urea, N-(3-tripropoxysilylethyl)urea, N-(3-ethoxydipropoxysilylethyl)urea, N-(3-dimethoxypropoxysilylethyl)urea, N-(3-methoxydipropoxysilylethyl)urea, N-(3-trimethoxysilylbutyl)urea, N-(3-triethoxysilylbutyl)urea, N-(3-tripropoxysilylbutyl)urea, 3-(m-aminophenoxy)propyltrimethoxysilane (manufactured by Azmax Corporation: trade name of SLA0598.0), m-aminophenyltrimethoxysilane (manufactured by Azmax Corporation: trade name of SLA0599.0), p-aminophenyltrimethoxysilane (manufactured by Azmax Corporation: trade name of SLA0599.1), aminophenyltrimethoxysilane (manufactured by Azmax Corporation: trade name of SLA0599.2) and the like.

Examples of silane coupling agents also include, but are not limited to, 2-(trimethoxysilylethyl)pyridine (manufactured by Azmax Corporation: trade name of S1T8396.0), 2-(triethoxysilylethyl)pyridine, 2-(dimethoxysilylmethylethyl)pyridine, 2-(diethoxysilylmethylethyl)pyridine, (3-triethoxysilylpropyl)-t-butyl carbamate, (3-glycidoxypropyl)triethoxysilane, tetramethoxysilane, tetraethoxysilane, tetra-n-propoxysilane, tetra-i-propoxysilane, tetra-n-butoxysilane, tetra-i-butoxysilane, tetra-t-butoxysilane, tetrakis(methoxyethoxysilane), tetrakis(methoxy-n-propoxysilane), tetrakis(ethoxyethoxysilane), tetrakis(methoxyethoxyethoxysilane), bis(trimethoxysilyl)ethane, bis(trimethoxysilyl)hexane, bis(triethoxysilyl)methane, bis(triethoxysilyl)ethane, bis(triethoxysilyl)ethylene, bis(triethoxysilyl)octane, bis(triethoxysilyl)octadiene, bis[3-(triethoxysilyl)propyl]disulfide, bis[3-(triethoxysilyl)propyl]tetrasulfide, di-t-butoxydiacetoxysilane, di-i-butoxyaluminoxytriethoxysilane, phenylsilanetriol, methylphenylsilanediol, ethylphenylsilanediol, n-propylphenylsilanediol, isopropylphenylsilanediol, n-butylphenylsilanediol, isobutylphenylsilanediol, tert-butylphenylsilanediol, diphenylsilanediol, dimethoxydiphenylsilane, diethoxydiphenylsilane, dimethoxydi-p-tolylsilane, ethylmethylphenylsilanol, n-propylmethylphenylsilanol, isopropylmethylphenylsilanol, n-butylmethylphenylsilanol, isobutylmethylphenylsilanol, tert-butylmethylphenylsilanol, ethyl n-propylphenylsilanol, ethylisopropylphenylsilanol, n-butylethylphenylsilanol, isobutylethylphenylsilanol, tert-butylethylphenylsilanol, methyldiphenylsilanol, ethyldiphenylsilanol, n-propyldiphenylsilanol, isopropyldiphenylsilanol, n-butyldiphenylsilanol, isobutyldiphenylsilanol, tert-butyldiphenylsilanol, triphenylsilanol and the like.

The silane coupling agents listed above may be used alone or a plurality thereof may be used in combination. Of the silane coupling agents listed above, from the viewpoint of the storage stability, preferred are phenylsilanetriol, trimethoxyphenylsilane, trimethoxy(p-tolyl)silane, diphenylsilanediol, dimethoxydiphenylsilane, diethoxydiphenylsilane, dimethoxydi-p-tolylsilane, triphenylsilanol, and silane coupling agents having structures represented by the following formula:

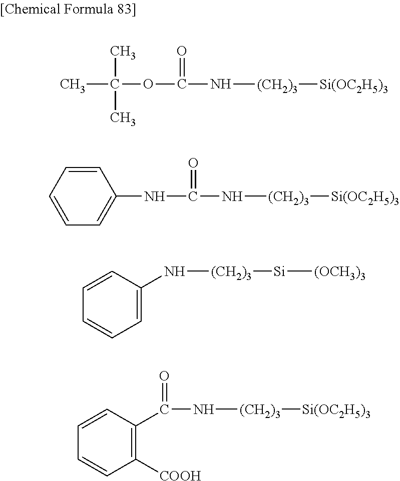

When the silane coupling agent is used, the mixing amount is preferably 0.01 to 20 parts by weight relative to 100 parts by weight of the polyimide precursor or polyimide resin (A).

### (L) Sensitizer

The photosensitive resin composition may optionally include a sensitizer in order to improve the photosensitivity. Examples of the sensitizer include Michler's ketone, 4,4′-bis(diethylamino)benzophenone, 2,5-bis(4′-diethylaminobenzal)cyclopentane, 2,6-bis(4′-diethylaminobenzal)cyclohexanone, 2,6-bis(4′-diethylaminobenzal)-4-methylcyclohexanone, 4,4′-bis(dimethylamino)chalcone, 4,4′-bis(diethylamino)chalcone, p-dimethylaminocinnamilideneindanone, p-dimethylaminobenzylideneindanone, 2-(p-dimethylaminophenylbiphenylene)-benzothiazole, 2-(p-dimethylaminophenylvinylene)benzothiazole, 2-(p-dimethylaminophenylvinylene)isonaphthothiazole, 1,3-bis(4′-dimethylaminobenzal)acetone, 1,3-bis(4′-diethylaminobenzal)acetone, 3,3′-carbonyl-bis(7-diethylaminocoumarin), 3-acetyl-7-dimethylaminocoumarin, 3-ethoxycarbonyl-7-dimethylaminocoumarin, 3-benzyloxycarbonyl-7-dimethylaminocoumarin, 3-methoxycarbonyl-7-diethylaminocoumarin, 3-ethoxycarbonyl-7-diethylaminocoumarin, N-phenyl-N′-ethylethanolamine, N-phenyldiethanolamine, N-p-tolyldiethanolamine, N-phenylethanolamine, 4-morpholinobenzophenone, isoamyl dimethylaminobenzoate, isoamyl diethylaminobenzoate, 2-mercaptobenzimidazole, 1-phenyl-5-mercaptotetrazole, 2-mercaptobenzothiazole, 2-(p-dimethylaminostyryl)benzoxazole, 2-(p-dimethylaminostyryl)benzthiazole, 2-(p-dimethylaminostyryl)naphtho(1,2-d)thiazole, 2-(p-dimethylaminobenzoyl)styrene, 2′-(phenylimino) diethanol and the like. These can be used alone or in combination of two to five thereof.

When the photosensitive resin composition includes a sensitizer, the mixing amount of the sensitizer is preferably 0.1 to 25 parts by weight relative to 100 parts by weight of the polyimide precursor or polyimide resin (A).

### (M) Polymerization Inhibitor

The photosensitive resin composition may optionally include a polymerization inhibitor in order to improve the stability of the viscosity and photosensitivity of the photosensitive resin composition during storage, particularly in a solution containing a solvent. It is possible to use, as the polymerization inhibitor, for example, hydroquinone, N-nitrosodiphenylamine, p-tert-butylcatechol, phenothiazine, N-phenylnaphthylamine, ethylenediaminetetraacetic acid, 1,2-cyclohexanediaminetetraacetic acid, glycol ether diaminetetraacetic acid, 2,6-di-tert-butyl-p-methylphenol, 5-nitroso-8-hydroxyquinoline, 1-nitroso-2-naphthol, 2-nitroso-1-naphthol, 2-nitroso-5-(N-ethyl-N-sulfopropylamino)phenol, N-nitroso-N-phenylhydroxylamineammonium salt, N-nitroso-N(1-naphthyl)hydroxylamineammonium salt and the like.

### <Method for Producing Cured Relief Pattern and Semiconductor Device>

The method for producing a cured relief pattern of the present disclosure includes the following steps:
(1) a step of applying the above-mentioned photosensitive resin composition of the present disclosure onto a substrate to form a photosensitive resin layer on the substrate,
(2) a step of exposing the resin layer,
(3) a step of the exposed resin layer to form a relief pattern, and
(4) a step of subjecting the relief pattern to a heat treatment to form a cured relief pattern.

### (1) Resin Layer Formation Step

In this step, the photosensitive resin composition is applied onto a substrate, and then dried as necessary to form a photosensitive resin layer. It is possible to use, as the application method, methods conventionally used for the application of a photosensitive resin composition, for example, a method of applying using a spin coater, a bar coater, a blade coater, a curtain coater or a screen-printing machine, or a method of spray coating using a spray coater.

### (2) Exposure Step

In this step, the resin layer formed as mentioned above is exposed through a photomask or a reticle having a pattern or directly, using an exposure device such as a contact aligner, a mirror projection, or a stepper.

### (3) Relief Pattern Formation Step

In this step, the unexposed area of the exposed photosensitive resin layer is developed and removed. As the developing method for developing a photosensitive resin layer after exposure (irradiation), any method can be selected and used from conventionally known methods of developing a photoresist, for example, a rotary spray method, a paddle method and an immersion method accompanied by an ultrasonic treatment. After development, for the purpose of adjusting the shape of the relief pattern, post-development baking may be carried out by a combination of an arbitrary temperature and time, as necessary.

As the developer used for development, for example, a good solvent for the photosensitive resin composition or a combination of a good solvent and a poor solvent is preferable. As the good solvent, for example, N-methyl-2-pyrrolidone, N-cyclohexyl-2-pyrrolidone, N,N-dimethylacetamide, cyclopentanone, cyclohexanone, γ-butyrolactone and α-acetyl-γ-butyrolactone are preferable. As the poor solvent, for example, toluene, xylene, methanol, ethanol, isopropyl alcohol, ethyl lactate, propylene glycol methyl ether acetate and water are preferable. When a good solvent and a poor solvent are mixed and used, it is preferable to adjust the ratio of the poor solvent to the good solvent in accordance with the solubility of the polymer in the photosensitive resin composition. Two or more solvents may be used, for example, a plurality thereof may be used in combination.

### (4) Cured Relief Pattern Formation Step

In this step, the relief pattern obtained by the above development is subjected to a heat treatment to dilute the photosensitive component, and the polyimide precursor (A) is imidized to convert it into a cured relief pattern (cured film) composed of a polyimide. It is possible to select, as the method of a heat treatment, for example, various methods such as those using a hot plate, an oven, and a temperature raising oven capable of setting a temperature program. The heat treatment can be carried out under the conditions, for example, at 160° C. to 350° C. for 30 minutes to 5 hours. In order to further improve the copper adhesion, the temperature of the heat treatment is preferably 350° C. or lower, more preferably 230° C. or lower, still more preferably 200° C. or lower, and yet more preferably 180° C. or lower. In order to further suppress copper migration, the temperature is preferably 200° C. or higher, and more preferably 230° C. or higher. Air may be used as an atmosphere gas during heat-curing, and an inert gas such as nitrogen or argon can also be used.

### <Polyimide Film>

The polyimide film (cured film) of the present disclosure can be produced by curing the photosensitive resin composition of the present disclosure, and the present disclosure also provides a cured film formed from a cured product of the photosensitive resin composition of the present disclosure. For example, the photosensitive resin composition including the polyimide resin (A) of the present disclosure can be used to produce a polyimide film based on the above-mentioned method for producing a cured relief pattern. For example, a polyimide film may be produced by imidizing the photosensitive resin composition including the polyimide precursor (A) of the present disclosure to form a polyimide cured product having an imidization rate of 80 to 100%. Also in this case, the polyimide film can be produced based on the above-mentioned method for producing a cured relief pattern. The structure of the polyimide contained in the cured relief pattern formed from the polyimide precursor composition is represented by the following general formula.

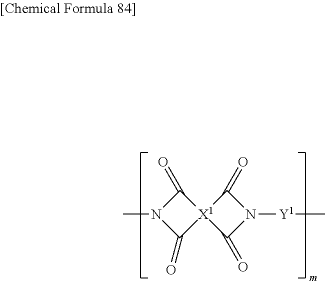

Preferred X₁ and Y₁ in the general formulas (4) and (4′) are also preferable in the polyimide having the structure represented by the above general formula for the same reason. In the above general formula, the number of repeating units m is not particularly limited, but may be an integer of 2 to 150.

### <Semiconductor Device>

It is preferable that the semiconductor device has a cured relief pattern obtained by the above-mentioned method for producing a cured relief pattern. The semiconductor device preferably includes a substrate which is a semiconductor element, and a cured relief pattern of a polyimide formed on the substrate by the above-mentioned method for producing a cured relief pattern. The semiconductor device can be produced by using a semiconductor element as a substrate and by using the method for producing a cured relief pattern of the present disclosure as part of the production process. More specifically, the semiconductor device can be produced by a method for producing a semiconductor device, which includes forming a cured relief pattern formed by the method for producing a cured relief pattern of the present disclosure as a surface protective film, an interlayer insulating film, a rewiring insulating film, a protective film for flip-chip devices, or a protective film of a semiconductor device having a bump structure.

### <Display Device>

The display device is preferably a display device comprising a display element and a cured film provided on an upper portion of the display element, wherein the cured film is the cured relief pattern mentioned above. Here, the cured relief pattern may be laminated in direct contact with the display element or may be laminated with another layer interposed therebetween. Examples of the cured film include surface protective films, insulating films and flattening films for TFT liquid crystal display elements and color filter elements; protrusions for MVA type liquid crystal display devices; and partition walls for organic EL element cathodes.

The photosensitive resin composition of the present disclosure is preferably a photosensitive resin composition for forming an insulating member or an interlayer insulating film. The photosensitive resin composition can also be used to form a surface protective film, an interlayer insulating film, a rewiring insulating film, a protective film for flip chip devices, or a protective film for a semiconductor device having a bump structure. In addition to application to semiconductor devices as mentioned above, the photosensitive resin composition of the present disclosure is also useful in applications such as interlayer insulation of multilayer circuits, cover-coating of flexible copper clad plates, solder resist films, and liquid crystal alignment films.

### EXAMPLES

Examples of the present disclosure will be described in detail below, but the embodiments are not limited thereto. In the Examples, Comparative Examples and Production Examples, the physical properties of the polyimide precursor or the photosensitive resin composition were measured and evaluated according to the following methods.

### <Measurement and Evaluation Methods>

### (1) Weight-Average Molecular Weight

The weight-average molecular weight (Mw) of each resin was measured using the gel permeation chromatography method (standard polystyrene conversion) under the following conditions.
Pump: JASCO PU-980
Detector: JASCO RI-930
Column Oven: JASCO CO-965, 40° C.
Columns: Shodex KD-806, two in series, manufactured by Showa Denko K.K., or
Shodex 805M/806M in series, manufactured by Showa Denko K.K.
Standard Monodisperse Polystyrene: Shodex STANDARD SM-105, manufactured by Showa Denko K.K.
Mobile Phase: 0.1 mol/L LiBr/N-methyl-2-pyrrolidone (NMP)
Flow rate: 1 mL/min

### (2) Fabrication of Cured Relief Pattern for Evaluation of Copper Voids

Titanium (Ti)having a thickness of 200 nm and copper (Cu) having a thickness of 400 nm were sputtered in this order onto a 6-inch silicon wafer (manufactured by Fujimi Electronics Industry Co., Ltd., thickness of 625±25 μm) using a sputtering device (Model L-440S-FHL, manufactured by Canon Anelva Corporation). Subsequently, a photosensitive resin composition prepared by the method mentioned later was spin-coated on this wafer using a coater developer (model D-Spin60A, manufactured by SOKUDO Co., Ltd.), and prebaked on a hot plate at 110° C. for 180 seconds to form a coating film having a thickness of about 10 μm. Using a test patterned mask, the coating film was irradiated with i-rays at energy of 650 mJ/cm² by a Prisma GHI (manufactured by Ultratech Inc). The coating was then spray-developed with cyclopentanone as a developer by a coating developer (Model D-Spin60A, manufactured by SOKUDO Co., Ltd.) during the time calculated by multiplying the time, which is required for the unexposed area to be completely dissolved and disappeared, by 1.4, and subjected to rotary spray rinsing with propylene glycol methyl ether acetate for 10 seconds to obtain a relief pattern on Cu.

The wafer on which the relief pattern was formed on Cu was subjected to a heat treatment using a temperature-rising programmable curing furnace (Model VF-2000, manufactured by Koyo Lindberg Ltd.) at 230° C. for 2 hours in a nitrogen atmosphere to obtain a cured relief pattern made of resin having a thickness of about 6 to 9 μm on Cu.

### (3) High-Temperature Storage Test of Cured Relief Pattern on Cu and Subsequent Evaluation of Void Area

The wafer on which the cured relief pattern was formed on Cu was heated in air at 150° C. for 168 hours using a temperature-rising programmable curing furnace (Model VF-2000, manufactured by Koyo Lindberg Ltd.). Subsequently, the resin layer on Cu was entirely removed by plasma etching using a plasma surface treatment device (Model EXAM, manufactured by Shinko Seiki Co., Ltd.), and the area where the resin was originally located was observed under the following conditions to evaluate copper voids. The plasma etching conditions are as follows:
Output: 133 W
Gas type and flow rate: O₂: 40 mL/min+CF4: 1 mImin
Gas pressure: 50 Pa
Mode: Hard mode
Etching time: 4,200 seconds

The Cu surface from which the resin layer was entirely removed was observed under the following conditions using FE-SEM (Model S-4800, manufactured by Hitachi High-Tech Corporation), and the area of voids on the surface of the Cu layer was calculated using image analysis software (Azokun, manufactured by Asahi Kasei Corporation).

### <Observation Conditions>

Acceleration voltage: 20 kV
SE detector: mixed, BSE-L (L.A. 5)
Probe current: High
Working distance: 8 mm
Tilt: 0°
Observation magnification: 1,000 times

When the photosensitive resin composition mentioned in Comparative Example 1 was evaluated, the total area of voids was taken as 100%, and the total area ratio of voids is less than 50% was rated “A”, the total area ratio of voids is 50% or more and less than 70% was rated “B”, the total area ratio of voids is 70% or more and less than 100% was rated “C”, and the total area ratio of voids is 100% or more was rated “D”. If rating is B or higher, the composition can be suitably used as a cured relief pattern for semiconductors.

### (4) Evaluation of Copper Adhesion

Titanium (Ti)having a thickness of 200 nm and copper (Cu) having a thickness of 400 nm were sputtered in this order onto a 6-inch silicon wafer (manufactured by Fujimi Electronics Industry Co., Ltd., thickness of 625±25 μm) using a sputtering device (Model L-440S-FHL, manufactured by Canon Anelva Corporation). Subsequently, a photosensitive resin composition was spin-coated and dried on this wafer so that the film thickness after curing would be about 9 μm, and then the entire surface was exposed at 800 mJ/cm² by a parallel light mask aligner (Model PLA-501FA, manufactured by Canon Inc.). Using a temperature-rising programmable curing furnace (Model VF-2000, manufactured by Koyo Lindberg Ltd.), the film was heated for 2 hours in a nitrogen atmosphere at the temperatures shown in Tables 1 to 4 to obtain a cured relief pattern (thermally cured polyimide film). In accordance with JIS K 5600-5-6 standard cross-cut method, the adhesive properties between the copper substrate and the cured resin coating film of the heat-treated film were evaluated by the following criteria. If rating is B or higher, the pattern can be suitably used as a cured relief pattern for semiconductors.

A: Those in which the number of grids of the cured resin coating film adhered to the substrate is 100.

B: Those in which the number of grids of the cured resin coating film adhered to the substrate is 80 or more to less than 100.

C: Those in which the number of grids of the cured resin coating film adhered to the substrate is 40 or more to less than 80.

D: Those in which the number of grids of the cured resin coating film adhered to the substrate is less than 40.

(5) b-Hast Test

On a silicon wafer, a TEG wafer on which comb-shaped Cu wiring with a line/space of 10 μm/10 μm and a height of 5 m was formed was prepared. The TEG wafer was immersed in an aqueous 1% acetic acid solution for 1 minute, washed with running ion-exchanged water, and dried by an air gun. Then, oxygen plasma was carried out using low pressure plasma (EXAM, manufactured by Shinko Seiki Co., Ltd.) at 40 mL/min, 133 W and 50 Pa for 20 seconds. Thereafter, the photosensitive resin composition was spin-coated using a coater developer (D-Model Spin 60A, manufactured by SOKUDO Co., Ltd.) so that the film thickness would be 10 μm, and pre-baked on a hot plate at 110° C. for 180 seconds to form a coating film on the TEG wafer. Then, the film was exposed at 800 mJ/cm² using a parallel light mask aligner (Model PLA-501FA, manufactured by Canon Inc.). At this time, in order to ensure electrical continuity during the b-HAST test, the Cu electrode portion was exposed to light while being masked so as not to be irradiated with light, and the unexposed area was removed by the subsequent development. After 30 minutes or more had elapsed since the exposure, the film was subjected to rotary spray development by a coater developer (Model D-Spin 60A, manufactured by SOKUDO Co., Ltd.) at 23° C. using cyclopentanone as a developer for a time 1.4 times the time required for the unexposed areas to completely dissolve and disappear, followed by rotary spray rinsing with propylene glycol monomethyl ether acetate for 10 seconds. Thereafter, the film was heated for 2 hours in a temperature-rising programmable curing oven (Model VF-2000, manufactured by Koyo Lindberg Ltd.) in a nitrogen atmosphere at the temperatures shown in Tables 2 to 4 to obtain a cured relief pattern.

Using a highly accelerated life tester HAST chamber (EHS-222M, manufactured by Espec Corporation), a b-HAST test was carried out at 130° C. and 85% RH with an applied voltage of 50 V. The insulation resistance between the copper wirings was measured at 30-minute intervals, and a value of 1×104Ω or less was defined a dielectric breakdown. The time from the start of the test to the dielectric breakdown was calculated and evaluated based on the following criteria. If rating is D or higher, the pattern can be suitably used as a cured relief pattern for semiconductors.

A: 250 Hours or more until insulation breakdown.

B: 200 Hours or more to less than 250 hours until insulation breakdown.

C: 150 Hours or more to less than 200 hours until insulation breakdown.

D: 100 Hours or more to less than 150 hours until insulation breakdown.

E: Less than 100 hours until insulation breakdown.

### PRODUCTION EXAMPLES

### Production Example 1: Synthesis of (A) Polyimide Precursor A1

In a 2 L separable flask, 124.0 g of 4,4′-oxydiphthalic dianhydride (ODPA) and 29.4 g of 3,3′,4,4′-biphenyltetracarboxylic dianhydride (BPDA) were charged, and 131.2 g of 2-hydroxyethyl methacrylate (HEMA) and 400 mL of y-butyrolactone (hereinafter referred to as GBL) were added and, after stirring at room temperature, 81.5 g of pyridine was added while stirring to obtain a reaction mixture. After completion of heat generation due to the reaction, the reaction mixture was allowed to cool to room temperature and left to stand for 16 hours.

Next, under ice cooling, a solution prepared by dissolving 206.3 g of dicyclohexylcarbodiimide (DCC) in 200 mL of γ-butyrolactone was added to the reaction mixture over 20 minutes with stirring, and then a suspension prepared by dissolving 93.0 g of 4,4′-oxydianiline (ODA) in 350 mL of γ-butyrolactone was added over 30 minutes with stirring. After stirring for an additional 4 hours at room temperature, 30 mL of ethyl alcohol was added and, after stirring for 1 hour, 400 mL of γ-butyrolactone was added. The precipitate formed in the reaction mixture was removed by filtration to obtain a reaction solution.

The reaction solution thus obtained was added to 3 L of ethyl alcohol to produce a precipitate composed of a crude polymer. The crude polymer thus obtained was separated by filtration and dissolved in 1.5 L of tetrahydrofuran to obtain a crude polymer solution. The crude polymer solution thus obtained was added dropwise in 28 L of water to precipitate a polymer, and the precipitate thus obtained was filtered and then dried in vacuum to obtain a powdered polymer (polyimide precursor A1). The molecular weight of the polyimide precursor A1 was measured by gel permeation chromatography (in terms of standard polystyrene) and found that the weight-average molecular weight (Mw) was 24,000.

### Production Example 2: Synthesis of (A) Polyimide Precursor A2

In the same manner as in Production Example 1 mentioned above, except that 147.1 g of 3,3′,4,4′-biphenyltetracarboxylic dianhydride (BPDA) was used instead of 124.0 g of 4,4′-oxydiphthalic dianhydride (ODPA) and 29.4 g of 3,3′,4,4′-biphenyltetracarboxylic dianhydride (BPDA), a reaction was carried out to obtain a polymer (polyimide precursor A2). The molecular weight of the polyimide precursor A2 was measured by gel permeation chromatography (in terms of standard polystyrene), and the weight-average molecular weight (Mw) was 24,000.

### Production Example 3: Synthesis of (A) Polyimide Precursor A3

In the same manner as in Production Example 1 mentioned above, except that 155.1 g of 4,4′-oxydiphthalic dianhydride (ODPA) was used instead of 124.0 g of 4,4′-oxydiphthalic dianhydride (ODPA) and 29.4 g of 3,3′,4,4′-biphenyltetracarboxylic dianhydride (BPDA), a reaction was carried out to obtain a polymer (polyimide precursor A3). The molecular weight of the polyimide precursor A3 was measured by gel permeation chromatography (in terms of standard polystyrene), and the weight-average molecular weight (Mw) was 21,000.

### Production Example 4: Synthesis of (A) Polyimide Precursor A4

In the same manner as in Production Example 1 mentioned above, except that 155.1 g of 4,4′-oxydiphthalic dianhydride (ODPA) was used instead of 124.0 g of 4,4′-oxydiphthalic dianhydride (ODPA) and 29.4 g of 3,3′,4,4′-biphenyltetracarboxylic dianhydride (BPDA), and 98.6 g of 2,2′-dimethylbiphenyl-4,4′-diamine (m-TB) was used instead of 93.0 g of 4,4′-oxydianiline (ODA), a reaction was carried out to obtain polymer (A4). The molecular weight of the polymer (A4) was measured by gel permeation chromatography (in terms of standard polystyrene), and the weight-average molecular weight (Mw) was 21,000.

### Production Example 5: Synthesis of (A) Polyimide Precursor A5

In the same manner as in Production Example 1 mentioned above, except that 155.1 g of 4,4′-oxydiphthalic dianhydride (ODPA) was used instead of 124.0 g of 4,4′-oxydiphthalic dianhydride (ODPA) and 29.4 g of 3,3′,4,4′-biphenyltetracarboxylic dianhydride (BPDA), and 49.2 g of 1,4-phenylenediamine (pPD) was used instead of 93.0 g of 4,4′-oxydianiline (ODA), a reaction was carried out to obtain a polymer (polyimide precursor A5). The molecular weight of the polyimide precursor A5 was measured by gel permeation chromatography (in terms of standard polystyrene), and the weight-average molecular weight (Mw) was 21,000.

### Production Example 6: (A) Synthesis of Polyimide Precursor A6

In the same manner as in Production Example 1 mentioned above, except that 62 g of 4,4′-oxydiphthalic dianhydride (ODPA) and 88.3 g of pyromellitic dianhydride (PMDA) were used instead of 155.1 g of 4,4′-oxydiphthalic dianhydride (ODPA) in Production Example 4, a reaction was carried out to obtain a polymer (polyimide precursor A6). The molecular weight of the polyimide precursor A6 was measured by gel permeation chromatography (in terms of standard polystyrene), and the weight-average molecular weight (Mw) was 28,000.

### Production Example 7: Synthesis of (A) Polyimide Resin A7

In a nitrogen-purged three-necked flask equipped with a Dean-Stark extraction apparatus, 200 g of N-methyl-2-pyrrolidone (hereinafter referred to as NMP) and 33.1 g (0.012 mol) of 6-(4-aminophenoxy)biphenyl-3-amine (PDPE) were charged and dissolved, and 24.8 g (0.1 mol) of bicyclo[2.2.2]oct-7-ene-2,3,5,6-tetracarboxylic dianhydride (BCD) and 50.0 g of toluene were added thereto, followed by heating to 180° C. After confirming that the theoretical amount of water and the added toluene were extracted in the Dean-Stark extraction apparatus, heating was stopped, followed by cooling to room temperature. The reaction solution thus obtained was added dropwise in 2,000 g of ion-exchanged water to precipitate a polymer, followed by filtration and further vacuum drying at 40° C. to obtain a powdered polymer (polyimide resin A7). The weight-average molecular weight of the polyimide resin A7 was measured by gel permeation chromatography (in terms of standard polystyrene) and found that Mw was 14,300.

### Production Example 8: Synthesis of (A) Polyimide Resin A8

In the same manner as in Production Example 7, except that NMP in Production Example 7 was changed to GBL, the amount of PDPE added was changed to 23.0 g (0.083 mol), and BCD was changed to 44.4 g (0.1 mol) of 4,4′-(hexafluoroisopropylidene)diphthalic anhydride (6FDA), a polyimide resin A8 was obtained. The weight-average molecular weight of the polyimide resin A8 was measured by gel permeation chromatography (in terms of standard polystyrene), and Mw was 14,000.

### Production Example 9: Synthesis of (A) Polyimide Resin A9

In the same manner as in Production Example 7, except that NMP in Production Example 7 was changed to GBL, PDPE was changed to 30.1 g (0.088 mol) of 9,9′-bis(4-aminophenyl)fluorene (BAFL), and BCD was changed to 19.6 g (0.1 mol) of 1,2,3,4-cyclobutanetetracarboxylic anhydride (CBDA), a polyimide resin A9 was obtained. The weight-average molecular weight of the polyimide resin A9 was measured by gel permeation chromatography (in terms of standard polystyrene), and Mw was 29,000.

### Production Example 10: Synthesis of (A) Polyimide Resin A10 (MOI-Modified BCD-PDPE)

In a nitrogen-purged three-necked flask equipped with a Dean-Stark extraction apparatus, 200 g of GBL and 33.1 g (0.12 mol) of PDPE were charged and dissolved, and 24.8 g (0.1 mol) of BCD and 50.0 g of toluene were added thereto, followed by heating to 180° C. After confirming that the theoretical amount of water and the added toluene were extracted in the Dean-Stark extraction apparatus, heating was stopped, followed by cooling to room temperature.

Next, 6.2 g of 2-isocyanatoethyl methacrylate (hereinafter referred to as MOI) was added at room temperature, followed by a reaction at room temperature for 12 hours. The reaction solution thus obtained was added dropwise in 2,000 g of ion-exchanged water to precipitate a polymer, followed by filtration and further vacuum drying at 40° C. to obtain a powdered polymer (polyimide resin A10). The weight-average molecular weight of the polyimide resin A10 was measured by gel permeation chromatography (standard polystyrene equivalent), and Mw was 15,200.

### Example 1

A photosensitive resin composition was prepared by the following method using the polyimide precursor A1, and the composition thus prepared was evaluated. (A) a polyimide precursor A1: 100 g of the polyimide precursor mentioned in Production Example 1, (B) a tetrazole derivative B1: 3 g of 1H-tetrazole-5-carboxylic acid (manufactured by Advanced ChemBlocks), (C) a photopolymerization initiator C1: 3 g of TR-PBG-3057 (manufactured by TRONLY), and (E) a radical polymerizable compound E1: 10 g ofNK Ester A-9300 (manufactured by Shin-Nakamura Chemical Co., Ltd.) were dissolved in a mixed solvent of (D) a solvent D1: 80 g of γ-butyrolactone (hereinafter referred to as GBL, manufactured by Mitsubishi Chemical Corporation) and a solvent D2: 20 g of dimethyl sulfoxide (hereinafter referred to as DMSO, manufactured by Toray Fine Chemicals Co., Ltd.). The viscosity of the solution thus obtained was adjusted to about 40 poise by adding a required amount of a solution of GBL:DMSO=80:20 (weight ratio) to obtain a photosensitive resin composition. The composition was evaluated according to the methods mentioned above. The results are shown in Table 1.

### Examples 2 to 51, Comparative Examples 1 to 13

The components other than the solvent were adjusted in the mixing ratios shown in Tables 1 to 4, and the other components were dissolved in the solvent and the viscosity was adjusted in the same manner as in Example 1 to prepare photosensitive resin compositions. Then, the evaluation of copper adhesion and copper voids or a b-HAST test was carried out to evaluate copper adhesion and copper migration performance. The results are shown in Tables 1 to 4. The compounds mentioned in Tables 1 to 4 are as follows.

### (A) Polyimide Precursor or Comparative Polymer

A1: Polyimide precursor mentioned in Production Example 1
A2: Polyimide precursor mentioned in Production Example 2
A3: Polyimide precursor mentioned in Production Example 3
A4: Polyimide precursor mentioned in Production Example 4
A5: Polyimide precursor mentioned in Production Example 5
A6: Polyimide precursor mentioned in Production Example 6
A7: Polyimide resin mentioned in Production Example 7
A8: Polyimide resin mentioned in Production Example 8
A9: Polyimide resin mentioned in Production Example 9
A10: Polyimide resin mentioned in Production Example 10
A1′: ZCR-1797H (acid-modified epoxy acrylate having a biphenyl skeleton, manufactured by Nippon Kayaku Co., Ltd.)

### (B) Tetrazole Derivative

B1: 1H-Tetrazole-5-carboxylic acid (manufactured by Advanced ChemBlocks)
B2: Ethyl 1H-Tetrazole-5-carboxylate (manufactured by Tokyo Chemical Industry Co., Ltd.)
B3: 1H-Tetrazole-5-acetic acid (manufactured by Tokyo Chemical Industry Co., Ltd.)
B4: Ethyl 1H-Tetrazole-5-acetate (manufactured by Tokyo Chemical Industry Co., Ltd.)
B5: 2-(2H-tetrazol-5-yl)butanedioic acid (manufactured by Enamine Building Blocks)
B6: 2,2-Bis(2-2H-tetrazol-5-yl)ethyl)propanedioic acid (manufactured by Chemieliva Pharmaceutical Co., Ltd.)
B7: 4-(1H-tetrazol-5-yl)benzoic acid (manufactured by Tokyo Chemical Industry Co., Ltd.)
B8: 1H-Tetrazole-5-propionic acid (manufactured by Enamine Building Blocks)
B1′: 5-amino-1H-tetrazole (manufactured by Tokyo Chemical Industry Co., Ltd.)
B2′: 5-Phenyltetrazole (manufactured by Tokyo Chemical Industry Co., Ltd.)
B3′: 1-Methyltetrazole (manufactured by Tokyo Chemical Industry Co., Ltd.)

### (C) Photopolymerization Initiator

C1: TR-PBG3057 (manufactured by CHANGZHOU TRONLY NEW ELECTRONIC MATERIALS Co., Ltd.)
C2: 1-Phenyl-1,2-propanedione-2-(O-benzoyl)oxime (product name KZ-941, manufactured by CHANGZHOU TRONLY NEW ELECTRONIC MATERIALS Co., Ltd.)
C3: Ethanone, 1-[9-ethyl-6-(2-methylbenzoyl)-9H-carbazol-3-yl]-, 1-(O-acetyloxime) (product name Irgacure OXE02, manufactured by BASF Corporation)

### (D) Solvent

D1: GBL (manufactured by Mitsubishi Chemical Corporation)
D2: DMSO (manufactured by Toray Fine Chemicals Co., Ltd.)

### (E) Radical Polymerization Initiator

E1: Tris-(2-acryloxyethyl)isocyanurate (product name: NK Ester A-9300, manufactured by Shin-Nakamura Chemical Co., Ltd.)
E2: Tetraethylene glycol dimethacrylate (product name: NK Ester 4G, manufactured by Shin-Nakamura Chemical Co., Ltd.)
E3: Methoxynonaethylene glycol monomethacrylate (product name: PME-400, manufactured by NOF Corporation)
E4: Pentaerythritol tetraacrylate (product name: A-TMMT, manufactured by Shin-Nakamura Chemical Co., Ltd.)
E5: Dipentaerythritol polyacrylate (product name: A-DPH, manufactured by Shin-Nakamura Chemical Co., Ltd.)

### (F) Thermal Crosslinking Agent

F1: Alkylated urea resin (product name: NIKALAC MX-290, manufactured by Sanwa Chemical Co., Ltd.)
F2: 1,3,4,6-Tetrakis(methoxymethyl)glycoluril (product name: NIKALAC MX-270, manufactured by Sanwa Chemical Co., Ltd.)

### (G) Heterocyclic Compound

G1: Benzotriazole (manufactured by Tokyo Chemical Industry Co., Ltd.)
G2: 5-Carboxybenzotriazole (manufactured by Tokyo Chemical Industry Co., Ltd.)
G3: 8-Azaadenine (manufactured by Tokyo Chemical Industry Co., Ltd.)

### (J) Organic Titanium Compound

J1: Diisopropoxytitanium bis(ethyl acetate) (product name: Orgatix TC-750, manufactured by Matsumoto Fine Chemical Co., Ltd.)

### (K) Adhesive Aid

K1: N-Phenyl-3-aminopropyltrimethoxysilane (product name: KBM573, manufactured by Shin-Etsu Chemical Co., Ltd.)
K2: (3-Triethoxysilylpropyl)-t-butylcarbamate (manufactured by Gelest Co., Ltd.)
K3: 2-(3,4-Epoxycyclohexyl)ethyltrimethoxysilane (manufactured by Tokyo Chemical Industry Co., Ltd.)
K4: 4,4-Carbonylbis(2-(((3-triethoxysilyl)propyl)amino)carbonyl)benzoic acid (manufactured in-house)
K5: 2-(3-Triethoxysilylpropylcarbamoyl)benzoic acid (manufactured in-house)

### (L) Sensitizer

L1: 2,2′-(Phenylimino)diethanol (manufactured by Kanto Chemical Co., Ltd.)

TABLE 1

| | | | | | | | | | | | | Photopoly- | Radical | | | |
|---|---|---|---|---|---|---|---|---|---|---|---|---|---|---|---|---|
| | | | | | | | | | | | | merization | polymerizable | Curing | Evaluation results | |
| | Polymer | | | | | Tetrazole derivative | | | | | | initiator | compound | temperature | Copper | Copper |
| | A1 | A2 | A3 | A4 | A1′ | B1 | B2 | B3 | B4 | B1′ | B2′ | C1 | E1 | [° C.] | voids | adhesion |
| Ex. 1 | 100 | | | | | 3 | | | | | | 3 | 10 | 230 | B | B |
| Ex. 2 | 100 | | | | | | 3 | | | | | 3 | 10 | 230 | B | B |
| Ex. 3 | 100 | | | | | | | 3 | | | | 3 | 10 | 230 | A | A |
| Ex. 4 | 100 | | | | | | | 15 | | | | 3 | 10 | 230 | A | B |
| Ex. 5 | 100 | | | | | | | | 3 | | | 3 | 10 | 230 | B | B |
| Ex. 6 | 100 | | | | | 3 | | | | | | 3 | 40 | 230 | B | B |
| Ex. 7 | 100 | | | | | | 3 | | | | | 3 | 40 | 230 | B | B |
| Ex. 8 | 100 | | | | | | | 3 | | | | 3 | 40 | 230 | A | A |
| Ex. 9 | 100 | | | | | | | 15 | | | | 3 | 40 | 230 | A | B |
| Ex. 10 | 100 | | | | | | | | 3 | | | 3 | 40 | 230 | B | B |
| Ex. 11 | 100 | | | | | | | 0 | | | | 3 | 40 | 230 | A | A |
| Ex. 12 | | 100 | | | | | | 3 | | | | 3 | 10 | 230 | A | A |
| Ex. 13 | | | 100 | | | | | 3 | | | | 3 | 10 | 230 | A | A |
| Ex. 14 | | | | 100 | | | | 3 | | | | 3 | 10 | 230 | A | A |
| Comp. Ex. 1 | 100 | | | | | | | | | 3 | | 3 | 10 | 230 | C | C |
| Comp. Ex. 2 | 100 | | | | | | | | | | 3 | 3 | 10 | 230 | C | C |
| Comp. Ex. 3 | 100 | | | | | | | | | 3 | | 3 | 40 | 230 | D | D |
| Comp. Ex. 4 | 100 | | | | | | | | | | 3 | 3 | 40 | 230 | D | D |
| Comp. Ex. 5 | | | | | 100 | | | 3 | | | | 3 | 10 | 230 | D | D |
| Comp. Ex. 6 | | | | | 100 | | | 3 | | | | 3 | 40 | 230 | D | D |

TABLE 2

| | | | Tetrazole | | | | | | | | | |
|---|---|---|---|---|---|---|---|---|---|---|---|---|
| | | | derivative | | | | | Radical | | | | Thermal |
| | | | | B3 | Photopolymerization | | | polymerizable | | | | crosslinking |
| | Polymer | | pKa | 3.4 | initiator | | | compound | | | | agent |
| | A2 | A3 | tPSA | 91.76 | C1 | C2 | C3 | E2 | E3 | E4 | E5 | F1 |
| Ex. 15 | 100 | | | 1 | | 4 | | 10 | | | | 1 |
| Ex. 16 | 40 | 60 | | 1 | | 4 | | 10 | | | | 1 |
| Ex. 17 | 40 | 60 | | 0.005 | | 4 | | 10 | | | | 1 |
| Ex. 18 | 40 | 60 | | 3 | | 4 | | 10 | | | | 1 |
| Ex. 19 | 40 | 60 | | 10 | | 4 | | 10 | | | | 1 |
| Ex. 20 | 40 | 60 | | 15 | | 4 | | 10 | | | | 1 |
| Ex. 21 | 40 | 60 | | 1 | 4 | | | 10 | | | | 1 |
| Ex. 22 | 40 | 60 | | 1 | | | 4 | 10 | | | | 1 |
| Ex. 23 | 40 | 60 | | 1 | | 4 | | 10 | | | | 1 |
| Ex. 24 | 40 | 60 | | 3 | | 4 | | 10 | | | | 1 |
| Ex. 25 | 40 | 60 | | 3 | | 4 | | 10 | | | | 1 |
| Ex. 26 | 40 | 60 | | 3 | | 4 | | 10 | | | | 1 |
| Ex. 27 | 40 | 60 | | 3 | | 4 | | 10 | | | | 1 |
| Ex. 28 | 40 | 50 | | 3 | | 4 | | | | | 10 | 1 |
| Ex. 29 | 40 | 60 | | 1 | | 4 | | | 10 | | | 1 |
| Ex. 30 | | 100 | | 1 | | 4 | | | | 10 | | 1 |
| Ex. 31 | | 100 | | 1 | | 4 | | | | | | 1 |

| | Organic | | | | | |
|---|---|---|---|---|---|---|
| | titanium | Adhesion | | Curing | Evaluation results | |
| | compound | aid | Sensitizer | temperature | | Copper |
| | J1 | K1 | L1 | [° C.] | bHast | adhesion |
| Ex. 15 | 0.5 | 1 | 10 | 200 | C | B |
| Ex. 16 | 0.5 | 1 | 10 | 200 | C | A |
| Ex. 17 | 0.5 | 1 | 10 | 200 | D | B |
| Ex. 18 | 0.5 | 1 | 10 | 200 | B | A |
| Ex. 19 | 0.5 | 1 | 10 | 200 | C | A |
| Ex. 20 | 0.5 | 1 | 10 | 200 | D | B |
| Ex. 21 | 0.5 | 1 | | 200 | C | A |
| Ex. 22 | 0.5 | 1 | | 200 | C | A |
| Ex. 23 | 0.5 | 1 | 10 | 230 | A | B |
| Ex. 24 | 0.5 | 1 | 10 | 230 | A | A |
| Ex. 25 | 0.5 | 1 | 10 | 250 | A | B |
| Ex. 26 | 0.5 | 1 | 10 | 280 | A | B |
| Ex. 27 | 0.5 | 1 | 10 | 350 | A | B |
| Ex. 28 | 0.5 | 1 | 10 | 200 | B | B |
| Ex. 29 | 0.5 | 1 | 10 | 200 | C | A |
| Ex. 30 | 0.5 | 1 | 10 | 200 | B | A |
| Ex. 31 | 0.5 | 1 | 10 | 200 | C | A |

TABLE 3

| | | | Tetrazole derivative | | | | | | | | | |
|---|---|---|---|---|---|---|---|---|---|---|---|---|
| | | | | B1 | B3 | B5 | B6 | B7 | B8 | Photopolymerization | Radical polymerizable | |
| | Polymer | | pKa | 2.3 | 3.4 | 2.7 | 1.5 | 3.6 | 4 | initiator | compound | |
| | A2 | A3 | tPSA | 91.76 | 91.76 | 129.1 | 183.5 | 91.76 | 91.76 | C2 | E1 | E2 |
| Ex. 32 | 40 | 60 | | | 3 | | | | | 4 | 40 | |
| Ex. 33 | 40 | 60 | | | 3 | | | | | 4 | 15 | |
| Ex. 34 | 40 | 60 | | | 1 | | | | | 4 | 10 | |
| Ex. 35 | 40 | 60 | | | 1 | | | | | 4 | 10 | |
| Ex. 36 | 40 | 60 | | | 1 | | | | | 4 | | 10 |
| Ex. 37 | 40 | 60 | | | 1 | | | | | 4 | | 10 |
| Ex. 38 | 40 | 60 | | | 1 | | | | | 4 | | 10 |
| Ex. 39 | 40 | 60 | | | 1 | | | | | 4 | | 10 |
| Ex. 40 | 40 | 60 | | | | 1 | | | | 4 | | 10 |
| Ex. 41 | 40 | 60 | | | | | 1 | | | 4 | | 10 |
| Ex. 42 | 40 | 60 | | 1 | | | | | | 4 | | 10 |
| Ex. 43 | 40 | 60 | | | | | | 1 | | 4 | | 10 |
| Ex. 44 | 40 | 60 | | | | | | | 1 | 4 | | 10 |

| | | | Organic | | | | | | | | Evaluation | |
|---|---|---|---|---|---|---|---|---|---|---|---|---|
| | Thermal crosslinking | | titanium | | | | | | | Curing | results | |
| | agent | | compound | Adhesion aid | | | | | Sensitizer | temperature | | Copper |
| | F1 | F2 | J1 | K1 | K2 | K3 | K4 | K5 | L1 | [° C.] | bHast | adhesion |
| Ex. 32 | 1 | | 0.5 | 1 | | | | | 10 | 200 | A | B |
| Ex. 33 | 1 | | 0.5 | 1 | | | | | 10 | 200 | B | B |
| Ex. 34 | | 1 | 0.5 | 1 | | | | | 10 | 200 | C | B |
| Ex. 35 | | | 0.5 | 1 | | | | | 10 | 200 | D | B |
| Ex. 36 | 1 | | 0.5 | | 1 | | | | 10 | 200 | C | A |
| Ex. 37 | 1 | | 0.5 | | | 1 | | | 10 | 200 | C | A |
| Ex. 38 | 1 | | 0.5 | | | | 0.5 | 0.5 | 10 | 200 | C | A |
| Ex. 39 | 1 | | 0.5 | | | | | | 10 | 200 | C | B |
| Ex. 40 | 1 | | 0.5 | 1 | | | | | 10 | 200 | C | A |
| Ex. 41 | 1 | | 0.5 | 1 | | | | | 10 | 200 | C | A |
| Ex. 42 | 1 | | 0.5 | 1 | | | | | 10 | 200 | C | A |
| Ex. 43 | 1 | | 0.5 | 1 | | | | | 10 | 200 | C | A |
| Ex. 44 | 1 | | 0.5 | 1 | | | | | 10 | 200 | C | A |

TABLE 4

| | | | | | | | | | | | | | | Heterocyclic | | |
|---|---|---|---|---|---|---|---|---|---|---|---|---|---|---|---|---|
| | | | | | | | | | Tetrazole derivative | | | | | compound | | |
| | | | | | | | | | | B3 | B1′ | B2′ | B3′ | G1 | G2 | G3 |
| | Polymer | | | | | | | | pKa | 3.4 | 5.9 | 4.3 | 1.1 | 8.4 | 3.5 | 12.8 |
| | A2 | A3 | A5 | A6 | A7 | A8 | A9 | A10 | tPSA | 91.8 | 80.5 | 54.5 | 43.6 | 41.6 | 78.9 | 93.4 |
| Ex. 45 | | | | | | | | | | 1 | | | | | | |
| Ex. 46 | | | 100 | | | | | | | 3 | | | | | | |
| Ex. 47 | | | | 100 | | | | | | 3 | | | | | | |
| Ex. 48 | | | | | 100 | | | | | 1 | | | | | | |
| Ex. 49 | | | | | | | | 100 | | 1 | | | | | | |
| Ex. 50 | | | | | | 100 | | | | 1 | | | | | | |
| Ex. 51 | | | | | | | 100 | | | 1 | | | | | | |
| Comp. | 40 | 60 | | | | | | | | | 1 | | | | | |
| Ex. 7 | | | | | | | | | | | | | | | | |
| Comp. | 40 | 60 | | | | | | | | | | 1 | | | | |
| Ex. 8 | | | | | | | | | | | | | | | | |
| Comp. | 40 | 60 | | | | | | | | | | | 1 | | | |
| Ex. 9 | | | | | | | | | | | | | | | | |
| Comp. | 40 | 60 | | | | | | | | | | | | 1 | | |
| Ex. 10 | | | | | | | | | | | | | | | | |
| Comp. | 40 | 60 | | | | | | | | | | | | | | 0.5 |
| Ex. 11 | | | | | | | | | | | | | | | | |
| Comp. | | | | | 100 | | | | | | | | | | | 0.5 |
| Ex. 12 | | | | | | | | | | | | | | | | |
| Comp. | 40 | 60 | | | | | | | | | | | | | 1 | |
| Ex. 13 | | | | | | | | | | | | | | | | |

| | | | | Thermal | | | | | | |
|---|---|---|---|---|---|---|---|---|---|---|
| | Photopoly- | Radical | | cross- | Organic | | | | Evaluation | |
| | merization | polymerizable | | linking | titanium | Adhesion | | Curing | results | |
| | initiator | compound | | agent | compound | aid | Sensitizer | temperature | | copper |
| | C2 | E1 | E2 | F1 | J1 | K1 | L1 | [° C.] | bHast | adhesion |
| Ex. 45 | 4 | | 10 | 1 | 0.5 | 1 | 10 | 230 | C | B |
| Ex. 46 | 4 | | 10 | 1 | 0.5 | 1 | 10 | 230 | C | B |
| Ex. 47 | 4 | | 10 | 1 | 0.5 | 1 | 10 | 230 | C | B |
| Ex. 48 | 4 | 40 | | 1 | 0.5 | 1 | 10 | 230 | A | B |
| Ex. 49 | 4 | 40 | | 1 | 0.5 | 1 | 10 | 230 | A | B |
| Ex. 50 | 4 | 40 | | 1 | 0.5 | 1 | 10 | 230 | B | B |
| Ex. 51 | 4 | 40 | | 1 | 0.5 | 1 | 10 | 230 | A | B |
| Comp. | 4 | | 10 | 1 | 0.5 | 1 | 10 | 200 | E | B |
| Ex. 7 | | | | | | | | | | |
| Comp. | 4 | | 10 | 1 | 0.5 | 1 | 10 | 200 | B | D |
| Ex. 8 | | | | | | | | | | |
| Comp. | 4 | | 10 | 1 | 0.5 | 1 | 10 | 200 | C | D |
| Ex. 9 | | | | | | | | | | |
| Comp. | 4 | | 10 | 1 | 0.5 | 1 | 10 | 200 | E | D |
| Ex. 10 | | | | | | | | | | |
| Comp. | 4 | | 10 | 1 | 0.5 | 1 | 10 | 200 | E | B |
| Ex. 11 | | | | | | | | | | |
| Comp. | 4 | 40 | | 1 | 0.5 | 1 | 10 | 230 | E | B |
| Ex. 12 | | | | | | | | | | |
| Comp. | 4 | | 10 | 1 | 0.5 | 1 | 10 | 200 | E | A |
| Ex. 13 | | | | | | | | | | |

As shown in Table 1, in the photosensitive resin compositions of Examples 3, 8 and 11 to 14, the copper adhesion was rated “A” and the suppression of copper voids was also rated “A”. In the photosensitive resin compositions of Examples 4 and 9, the suppression of copper voids was rated “A”, but the copper adhesion was rated “B”. In the photosensitive resin compositions of Examples 1 to 2, 5 to 7 and 10, both copper adhesion and suppression of copper voids were rated “B”. On the other hand, in Comparative Examples 1 and 2, both copper adhesion and suppression of copper voids were rated “C”, and in Comparative Examples 3 to 6, both suppression of copper voids and copper adhesion were rated “D”.

Referring to the results in Tables 2 to 4, Comparative Examples 7 to 13, which do not satisfy the requirements of the present disclosure, are unable to improve both copper adhesion and copper migration performance (b-HAST test results). On the other hand, Examples 15 to 51 show excellent performance in both adhesion and copper migration resistance. Comparisons of Comparative Examples 7 to 11 and Comparative Example 13 with Example 16, and comparisons of Comparative Example 12 with Example 47 show that the use of the tetrazole derivative (B) in the present disclosure improves the copper adhesion and copper migration performance. Comparative Examples 7 to 10 contain a tetrazole derivative, but do not have the structure of general formula (1) or (2), and the pKa and tPSA do not satisfy the preferred ranges of the present disclosure, and therefore sufficient effects are not obtained. Comparative Examples 11 to 13 contain a heterocyclic compound whose pKa and/or tPSA satisfy the preferred ranges of the present disclosure, but the heterocyclic compound is not a tetrazole derivative, and therefore do not provide sufficient effects.

Subsequently, referring to Examples, Examples 16 to 20 have compositions with different contents of the tetrazole derivative (B), but Examples 16, 18, and 19, in which the content is within a range of 0.01 to 10 parts by weight, have better copper adhesion and copper migration performance. When Example 16 is compared with Example 23, or Example 18 is compared with Examples 24 to 28, it is found that the copper migration property is improved by increasing the cure temperature, but the copper adhesion is better at 230° C. or lower, and more better at 200° C. or lower. When Comparing Example 31 is compared with Example 30, it is found that copper migration is improved by including the radical polymerizable compound (E). Furthermore, when Example 34 is compared with Example 33, it is found that the inclusion of the thermal crosslinking agent (F) improves the copper migration. When Example 38 is compared with Example 16, it is found that the inclusion of the adhesion promoter (G) improves the copper adhesion. Furthermore, when Example 33 is compared with Example 32, it is found that Example 32, in which the content of the radical polymerizable compound (E) is within a range of 20 to 80 parts by weight, exhibits better copper migration.

### INDUSTRIAL APPLICABILITY

By using the photosensitive resin composition according to the present disclosure, it is possible to obtain a cured relief pattern which has excellent copper adhesion and suppression of copper voids, and exhibits little copper migration in the b-HAST test. The photosensitive resin composition of the present disclosure can be suitably used in the field of photosensitive materials which are useful for producing electric and electronic materials such as semiconductor devices and multilayer wiring boards. More specifically, the composition can be used, for example, to form relief patterns of insulating materials for electronic components, passivation films, buffer coat films, interlayer insulating film and the like in semiconductor devices.

1. A photosensitive resin composition comprising:
(A) a polyimide precursor and/or a polyimide resin,
(B) a tetrazole derivative,
(C) a photopolymerization initiator, and
(D) a solvent,
wherein the tetrazole derivative (B) has a pKa of 1.3 to 4.1.

2. A photosensitive resin composition comprising:
(A) a polyimide precursor and/or a polyimide resin,
(B) a tetrazole derivative,
(C) a photopolymerization initiator, and
(D) a solvent,
wherein the tetrazole derivative (B) contains a compound represented by following general formula (1): 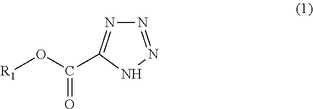
wherein, in formula (1), R₁ is a hydrogen atom, or a monovalent organic group selected from the group consisting of an alkyl group having 1 to 10 carbon atoms and an aryl group having 6 to 10 carbon atoms, and hydrogen atoms of the alkyl group and the aryl group may or may not be each independently substituted with at least one substituent selected from the group consisting of a halogen atom, a hydroxyl group, an alkoxysilyl group and an amino group,
or following general formula (2): 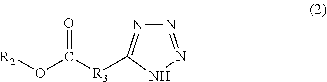
wherein, in formula (2), R₂ is a hydrogen atom, or a monovalent organic group selected from the group consisting of an alkyl group having 1 to 10 carbon atoms and an aryl group having 6 to 10 carbon atoms, R₃ is an alkylene group having 1 to 10 carbon atoms, and hydrogen atoms of the alkyl group, the aryl group and the alkylene group may or may not be each independently substituted with at least one substituent selected from the group consisting of a halogen atom, a hydroxyl group, an alkoxysilyl group and an amino group.

3. A photosensitive resin composition comprising:
(A) a polyimide precursor and/or a polyimide resin,
(B) a tetrazole derivative,
(C) a photopolymerization initiator, and
(D) a solvent,
wherein the tetrazole derivative (B) has a polar surface area (tPSA) of 81 to 200.

4. The photosensitive resin composition according to claim 1, wherein the content of the component (B) to 100 parts by weight of the component (A) is 0.01 to 10 parts by weight.

5. The photosensitive resin composition according to claim 1, wherein the tetrazole derivative (B) contains a compound represented by following general formula (3): 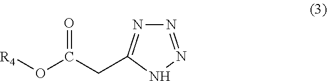
wherein, in formula (3), R₄ is a hydrogen atom, or a monovalent organic group selected from the group consisting of an alkyl group having 1 to 10 carbon atoms and an aryl group having 6 to 10 carbon atoms, and hydrogen atoms of the alkyl group and the aryl group may or may not be each independently substituted with at least one substituent selected from the group consisting of a halogen atom, a hydroxyl group, an alkoxysilyl group and an amino group.

6. The photosensitive resin composition according to claim 1, wherein the tetrazole derivative (B) contains a compound represented by the following formula:

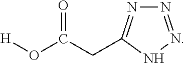

7. The photosensitive resin composition according to claim 1, further comprising (E) a radical polymerizable compound.

8. The photosensitive resin composition according to claim 7, wherein the content of the component (E) to 100 parts by weight of the component (A) is 20 to 80 parts by weight.

9. The photosensitive resin composition according to claim 1, wherein the photosensitive resin composition includes the polyimide precursor, and the polyimide precursor is represented by following general formula (4): 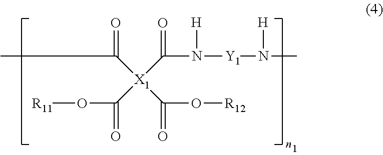
wherein, in formula (4), X₁ is a tetravalent organic group, Y₁ is a divalent organic group, n₁ is an integer of 2 to 150, and R₁₁ and R₁₂ each independently represent a hydrogen atom, or a monovalent organic group, and/or
the photosensitive resin composition includes the polyimide resin, and the polyimide resin includes a structural unit represented by following general formula (4′): 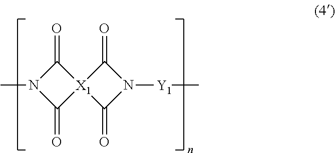
wherein, in formula (4′), X₁ is a tetravalent organic group, Y₁ is a divalent organic group, and n is an integer of 1 to 150.

10. The photosensitive resin composition according to claim 9, wherein, in the above general formula (4), at least one of R₁₁ and R₁₂ includes a structural unit represented by following general formula (5): 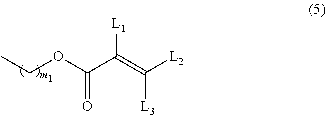
wherein, in formula (5), L₁, L₂ and L₃ are each independently a hydrogen atom, or a monovalent organic group having 1 to 3 carbon atoms, and m₁ is an integer of 2 to 10.

11. The photosensitive resin composition according to claim 9, wherein X₁ of the general formula (4′) is at least one selected from structures represented by following general formulas (6) to (14), or Y₁ of the above general formula (4′) is at least one selected from structures represented by following general formula (15) to (23):

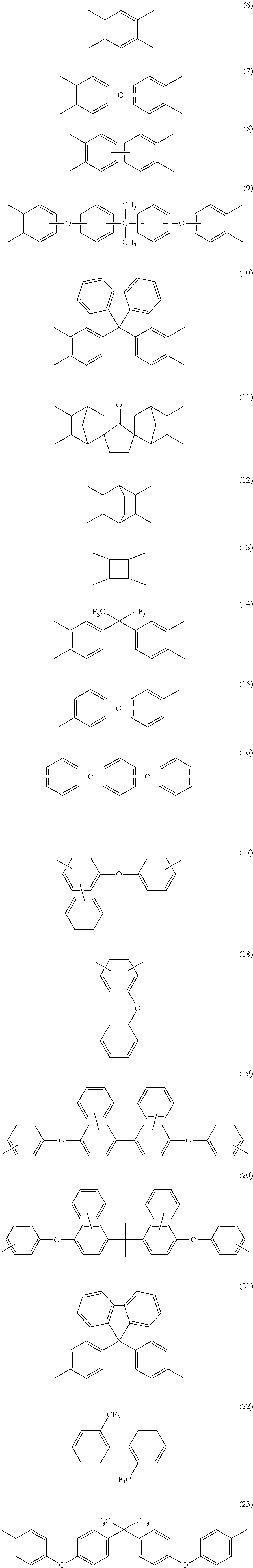

12. The photosensitive resin composition according to claim 1, further comprising (F) a thermal crosslinking agent.

13. The photosensitive resin composition according to claim 1, further comprising (K) an adhesion aid.

14. The photosensitive resin composition according to claim 1, wherein the photosensitive resin composition is a photosensitive resin composition for forming a surface protective film, an interlayer insulating film, a rewiring insulating film, a protective film for flip-chip devices, or a protective film of a semiconductor device having a bump structure.

15. A method for producing a cured relief pattern, which comprises:
(1) applying the photosensitive resin composition according to claim 1 onto a substrate to form a photosensitive resin layer on the substrate,
(2) exposing the photosensitive resin layer,
(3) developing the exposed photosensitive resin layer to form a relief pattern, and
(4) subjecting the relief pattern to a heat treatment to form a cured relief pattern.

16. The method for producing a cured relief pattern according to claim 15, wherein the heat treatment in the step (4) is a heat treatment at 350° C. or lower.

17. A cured film comprising a cured product of the photosensitive resin composition according to claim 1.

18. A method for producing a polyimide film, which comprises curing the photosensitive resin composition according to claim 1.
